(19) United States
(12) Patent Application Publication
(10) Pub. No.: US 2025/0289960 A1
(43) Pub. Date: Sep. 18, 2025

(54) MATERIAL KIT, CURABLE COMPOSITION, FILM FORMING METHOD, AND ARTICLE MANUFACTURING METHOD

(71) Applicant: CANON KABUSHIKI KAISHA, Tokyo (JP)

(72) Inventors: AYANO MASHIDA, Kanagawa (JP); MASANOBU OOTSUKA, Tokyo (JP); TOSHIKI ITO, Kanagawa (JP); JUMPEI SHIRONO, Kanagawa (JP)

(21) Appl. No.: 19/073,342

(22) Filed: Mar. 7, 2025

(30) Foreign Application Priority Data
Mar. 14, 2024 (JP) 2024-040189

(51) Int. Cl. C09D 4/00; C08K 5/3492; C08K 5/5397; C09D 7/20; C09D 7/63; C09D 11/38; C09J 163/04; G03F 7/028; G03F 7/09; G03F 7/11; G03F 7/16; G03F 7/20

(52) U.S. Cl. CPC C09D 4/00; C08K 5/34924; C08K 5/5397; C09D 7/20; C09D 7/63; C09D 11/38; C09J 163/04; G03F 7/028; G03F 7/094; G03F 7/11; G03F 7/162; G03F 7/168; G03F 7/2018

(57) ABSTRACT

A material kit includes a curable composition, and a layer forming composition configured to form an adhesion layer that adheres a substrate and the curable composition. The curable composition contains a polymerizable compound, a photopolymerization initiator, and a solvent. A contact angle of the curable composition to the adhesion layer is not more than 1.8[°], and the contact angle of a composition in a state in which the solvent is removed from the curable composition to the adhesion layer is not less than 11[°] and not more than 19[°].

### BACKGROUND OF THE INVENTION

### Field of the Invention

The present disclosure relates to a material kit, a curable composition, a film forming method, and an article manufacturing method.

### Description of the Related Art

For semiconductor devices and MEMS, requirements of micronization are increasing, and an imprint technique (optical imprint technique) has received a great deal of attention as a microfabrication technique. In the imprint technique, a curable composition is cured in a state in which a mold with a fine concave-convex pattern formed on the surface is in contact with the curable composition supplied (applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order.

An example of a pattern forming method using the imprint technique will be described. First, a curable composition in liquid form is discretely dropped (arranged) in a pattern formation region on a substrate. The droplets of the curable composition arranged in the pattern formation region spread on the substrate. This phenomenon is called pre-spreading. Next, a mold is brought into contact with (pressed against) the curable composition on the substrate.

Thus, the droplets of the curable composition spread to the whole region of the gap between the substrate and the mold by a capillary phenomenon. This phenomenon is called spreading. Also, by the capillary phenomenon, the curable composition fills concave portions that form the pattern of the mold. This phenomenon is called filling. Note that the time until spreading and filling are completed is called a filling time. If the filling of the curable composition is completed, the curable composition is irradiated with light to cure the curable composition. Then, the mold is released from the cured curable composition on the substrate. By executing these steps, the pattern of the mold is transferred to the curable composition on the substrate, and the pattern of the curable composition is formed. Here, the pattern of the curable composition formed on the substrate includes a residual film. The residual film is a cured film remaining between the substrate and a concave portion of the cured film of the curable composition (a convex portion of the pattern of the mold).

A photolithography step of fabricating a semiconductor device requires planarization of a substrate. For example, in an extreme ultraviolet exposure technique (EUV) as a photolithography technique attracting attention in recent years, the depth of focus at which a projected image is formed decreases as miniaturization advances, so the unevenness on the surface of a substrate to which a curable composition is supplied must be decreased to a few tens nm or less.

Flatness equivalent to that of EUV is required in an imprint technique as well, in order to improve the filling properties of a curable composition and the line width accuracy. As a planarization technique, there is known a technique of obtaining a flat surface by discretely dropping, on an uneven substrate, droplets of a curable composition in an amount corresponding to the unevenness, and curing the curable composition in a state in which a mold having a flat surface is in contact with the curable composition.

In the pattern forming method or planarization technique using the imprint technique, since the mold is brought into contact in a state in which the droplets of the curable composition dropped onto the substrate are not in contact with each other, bubbles are inevitably involved between the mold and the curable composition on the substrate. Along time is needed until the bubbles are diffused and disappear, and this is one of factors lowering productivity (throughput). Hence, there has been proposed a technique of bonding the droplets of the curable composition to each other before the curable composition on the substrate and the mold are brought into contact with each other (see Japanese Patent Laid-Open No. 2022-188736).

However, in the technique disclosed in Japanese Patent Laid-Open No. 2022-188736, since the droplets of the curable composition dropped on the substrate so spread at a high speed that the droplets bond to each other, the curable composition may extrude from a desired region (designed liquid film region).

The length of the curable composition extruded from the desired region is called an “extrusion amount”. The extruded curable composition causes an undesirable state in which it encroaches into an adjacent imprint region or adheres to the side wall of the mold.

To prevent the extrusion, a technique of suppressing excessive spread of a liquid film using a pinning effect is disclosed in Japanese Patent Laid-Open No. 2010-530641.

The inventors found a problem that even if droplets bond to each other and form a liquid film, the liquid film sometimes shrinks after that. If the liquid film shrinks, an incomplete edge filling defect that the curable composition does not spread to ends portion of the mold may occur. In Japanese Patent Laid-Open No. 2010-530641, a technique using the pinning effect to prevent extrusion is disclosed, but there is no mention about shrinkage of the liquid film.

### SUMMARY OF THE INVENTION

The present disclosure provides, for example, a new technique concerning a material kit.

The present invention in its one aspect provides a material kit including a curable composition, and a layer forming composition configured to form an adhesion layer that adheres a substrate and the curable composition, wherein the curable composition contains a polymerizable compound (a1), a photopolymerization initiator (b1), and a solvent (d1), a viscosity of the curable composition at 23° C. and at 1 atm is not less than 1.3 mPa·s and not more than 60 mPa·s, a content of the solvent (d1) with respect to a total volume of the polymerizable compound (a1), the photopolymerization initiator (b1), and the solvent (d1) is not less than 5 vol % and not more than 95 vol %, a boiling point of the solvent (d1) is less than 250° C. at 1 atm, a contact angle of the curable composition to the adhesion layer is not more than 1.8[°], and the contact angle of a composition in a state in which the solvent (d1) is removed from the curable composition to the adhesion layer is not less than 11[°] and not more than 19[°].

Further features of the present invention will become apparent from the following description of exemplary embodiments (with reference to the attached drawings).

Further features of the present invention will become apparent from the following description of exemplary embodiments (with reference to the attached drawings).

### BRIEF DESCRIPTION OF THE DRAWINGS

FIGS. 1A to 1G are views for explaining a pattern forming method (film forming method);

FIGS. 2A to 2G are views for explaining a pattern forming method (film forming method) by reverse imprinting;

FIGS. 3A to 3D are views for explaining the flow behavior of droplets of a curable composition during a waiting step; and

FIGS. 4A and 4B are views showing comparison between a conventional technique and the embodiment concerning gas confinement that occurs in a contact step.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate.

Furthermore, in the attached drawings, the same reference numerals are given to the same or similar configurations, and redundant description thereof is omitted.

When providing a new technique concerning a film forming method, the inventors found physical property conditions for allowing the droplets of a curable composition dropped (arranged) on a substrate to bond to each other to form a continuous liquid film and simultaneously preventing the liquid film from either spreading too much or shrinking. A material kit according to the embodiment, which includes a curable composition, and a layer forming composition configured to form an adhesion layer that adheres a substrate and the curable composition, will be described below.

### [Curable Composition]

A curable composition (A) of the present disclosure is a curable composition for inkjet. The curable composition (A) of the present disclosure is a composition containing at least a component (a1) as a polymerizable compound, a component (b1) as a photopolymerization initiator, and a component (d1) as a solvent.

In this specification, a cured film means a film cured by polymerizing the curable composition on a substrate. Note that the shape of the cured film is not particularly limited, so the film can have a pattern shape on the surface. Also, a cured film remaining between a recessed portion of the cured film of the curable composition (a projecting portion of a mold pattern) and the substrate will be called a residual film.

### <Component (a1): Polymerizable Compound>

The component (a1) is a polymerizable compound. In this specification, the polymerizable compound is a compound that reacts with a polymerizing factor (for example, a radical) generated from a polymerization initiator (the component (b1)), and forms a film made of a polymer compound by a chain reaction (polymerization reaction).

An example of the polymerizable compound as described above is a radical polymerizable compound. The polymerizable compound as the component (a1) can be formed by only one type of a polymerizable compound, and can also be formed by a plurality of types (one or more types) of polymerizable compounds.

Examples of the radical polymerizable compound are a (meth)acrylic compound, a styrene-based compound, a vinyl-based compound, an allylic compound, a fumaric compound, and a maleic compound.

The (meth)acrylic compound is a compound having one or more acryloyl groups or methacryloyl groups. Examples of a monofunctional (meth)acrylic compound having one acryloyl group or methacryloyl group are as follows, but the compound is not limited to these examples.

Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl(meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, cyanobenzyl (meth)acrylate, naphthalene methyl (meth)acrylate.

Examples of commercially available products of the above-described monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL); KAYARAD® TC110S, R-564, and R-128H (manufactured by NIPPON KAYAKU); NK Ester AMP-10G, AMP-20G, and A-LEN-10 (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); ACMO, DMAA, and DMAPAA (manufactured by Kohjin); and HRD-01 (manufactured by NIPPON SHOKUBAI).

Examples of a polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, o-, m-, or p-benzene di(meth)acrylate, and o-, m-, or p-xylylene di(meth)acrylate.

Examples of commercially available products of the above-described polyfunctional (meth)acrylic compounds are as follows, but the products are not limited to these examples.

Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); Ripoxy® VR-77, VR-60, and VR-90 (manufactured by Showa Highpolymer); OGSOL EA-0200 and OGSOL EA-0300 (manufactured by Osaka Gas Chemicals); and SR295 and SR355 (manufactured by Sartomer).

Note that in the above-described compound county, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the allylic compound are as follows, but the compound is not limited to these examples.

Allyl acetate, allyl benzoate, diallyl adipate, diallyl terephthalate, diallyl isophthalate, and diallyl phthalate.

Examples of the fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the component (a1) is formed by a plurality of types of compounds having one or more polymerizable functional groups, both a monofunctional polymerizable compound and a polyfunctional polymerizable compound are preferably included. The ratio of the polyfunctional polymerizable compound in the component (a1) is preferably 20 wt % or more, more preferably 25 wt % or more, and particularly preferably 40 wt % or more. This is because if a monofunctional compound and a polyfunctional compound are combined, a cured film having well-balanced performance, for example, a high mechanical strength, a high dry etching resistance, and a high heat resistance can be obtained.

The film forming method of the present disclosure requires a few milliseconds to a few hundreds of seconds until droplets of the curable composition (A) discretely arranged on a substrate combine with each other and form a practically continuous liquid film, so a waiting step (to be described later) is necessary. In this waiting step, the solvent (d1) is volatilized, but the polymerizable compound (a1) must not be volatilized. Accordingly, the boiling points of one or more types of polymerizable compounds included in the polymerizable compound (a1) at normal pressure are preferably 250° C. or more, more preferably 300° C. or more, and further preferably 350° C. or more. Also, to obtain a high dry etching resistance and a high heat resistance, the cured film of the curable composition (A) preferably contains at least a compound having a cyclic structure such as an aromatic structure, an aromatic heterocyclic structure, or an alicyclic structure. Note that the normal pressure is 1 atm (atmospheric pressure).

The boiling point of the polymerizable compound (a1) is almost correlated with the molecular weight. Therefore, the molecular weights of one or more types of polymerizable compounds included in the polymerizable compound (a1) are preferably 200 or more, more preferably 240 or more, and further preferably 250 or more. However, even when the molecular weight is 200 or less, the compound is preferably usable as the polymerizable compound (a1) of the present disclosure if the boiling point is 250° C. or more. As described above, the boiling points of one or more types of polymerizable compounds included in the polymerizable compound (a1) are preferably 250° C. or more at normal pressure.

In addition, the vapor pressure at 80° C. of the polymerizable compound (component (a1)) is preferably 0.001 mmHg or less. If the polymerizable compound (a1) includes one or more types of polymerizable compounds, the vapor pressures of the one or more types of polymerizable compounds at 80° C. are preferably 0.001 mmHg or less. This is so because, although it is favorable to heat the curable composition when accelerating volatilization of the solvent (component (d1)) (to be described later), it is necessary to suppress volatilization of the polymerizable compound (a1) during heating.

Note that the boiling point and the vapor pressure of each of various kinds of organic compounds at normal pressure can be calculated by, for example, Hansen Solubility Parameters in Practice (HSPiP) 5th Edition. 5.3.04.

<Ohnishi Parameter of Component (a1)>

It is known that a dry etching rate V of an organic compound, a number N of all atoms in the organic compound, a number N_{C} of all carbon atoms in a composition, and a number N_{O} of all oxygen atoms in the composition have a relationship of equation (1) below.

$$V ∝ N / ( {N}_{C} - {N}_{o} ) \qquad ( 1 )$$

where N/(N_{C}−N_{O}) is also called “Ohnishi Parameter” (to be referred to as “OP” hereinafter). For example, the specification of US-2020-0286740 has disclosed a technique of obtaining a photocurable composition having a high dry etching resistance by using a polymerizable compound having a small OP.

Equation (1) indicates that an organic compound having many oxygen atoms in a molecule or having few aromatic ring structures or alicyclic structures has a large OP and a high dry etching rate.

In the curable composition (A) according to the present disclosure, the OP of the component (a1) is 1.80 or more and 4.00 or less. The OP of the component (a1) is more preferably 2.00 or more and 3.50 or less, and particularly preferably 2.40 or more and 3.00 or less. When the OP of the component (a1) is 4.00 or less, the cured film of the curable composition (A) has a high dry etching resistance. Also, when the OP of the component (a1) is 1.80 or more, the cured film of the curable composition (A) can easily be removed when the underlayer is processed by using the cured film of the curable composition (A). When the component (a1) is formed by a plurality of types polymerizable compounds a₁, a₂, . . . , aₙ, the OP is calculated as a weighted average value (molar fraction weighted average value) based on the molar fraction as indicated by equation (2) below. If the component (a1) contains one or more types of polymerizable compounds, the OP of the component (a1) is calculated as the molar fraction weighted average value of an N/(Nc−No) value of each molecule of the one or more types of polymerizable compounds.

$$OP = {\sum }_{i = n} {n}_{i} {OP}_{i} = {n}_{1} {OP}_{1} + {n}_{2} {OP}_{2} + … + {n}_{n} {OP}_{n} \qquad ( 2 )$$

where OPₙ is the OP of the component aₙ, and nₙ is the molar fraction occupied by the component aₙ in the entire component (a1).

To set the OP of the component (a1) to 1.80 or more and 4.00 or less, a compound (a1-1) having two or more cyclic structures, in which at least one of the cyclic structures is an aromatic structure or an aromatic heterocyclic structure, is preferably contained at least as the component (a1).

<Compound (a1-1): Polymerizable Compound Having Aromatic Structure, Aromatic Heterocyclic Structure, or Alicyclic Structure>

The polymerizable compound (a1) according to the present disclosure may contain a polymerizable compound (a1-1) having an aromatic structure, an aromatic heterocyclic structure, or an alicyclic structure.

Examples of the cyclic structure are an aromatic structure, an aromatic heterocyclic structure, and an alicyclic structure.

The carbon number of the aromatic structure is preferably 6 to 22, more preferably 6 to 18, and further preferably 6 to 10. Practical examples of the aromatic ring are as follows.

A benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring.

Note that, of the above-described aromatic rings, a benzene ring or a naphthalene ring is preferable, and a benzene ring is more preferable. The aromatic ring can have a structure in which a plurality of rings are connected. Examples are a biphenyl ring and a bisphenyl ring.

The carbon number of the aromatic heterocyclic structure is preferably 1 to 12, more preferably 1 to 6, and further preferably 1 to 5. Practical examples of the aromatic heterocycle are as follows.

A thiophene ring, a furan ring, a pyrolle ring, an imidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiine ring, and a phenoxazine ring.

The carbon number of the alicyclic structure is preferably 3 or more, more preferably 4 or more, and further preferably 6 or more. In addition, the carbon number of the alicyclic structure is preferably 22 or less, more preferably 18 or less, further preferably 6 or less, and still further preferably 5 or less. Practical examples are as follows.

A cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydro dicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring.

Practical examples of the polymerizable compound (a1-1) having a boiling point of 250° C. or more are as follows, but the compound is not limited to these examples.

3-phenoxybenzyl acrylate (mPhOBzA, OP=2.54, boiling point=367.4° C., 80° C. vapor pressure=0.0004 mmHg, molecular weight=254.3)

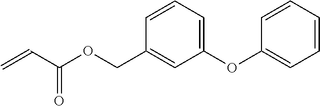 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

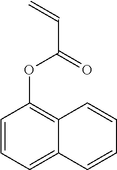

2-phenylphenoxyethyl acrylate (PhPhOEA, OP=2.57, boiling point=364.2° C., 80° C. vapor pressure=0.0006 mmHg, molecular weight=268.3)

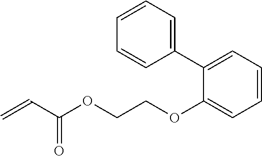 [SMILES: C=CC(=O)OCCOc1ccccc1-c1ccccc1]

1-naphthylmethyl acrylate (Na1MA, OP=2.33, boiling point=342.1° C., 80° C. vapor pressure=0.042 mmHg, molecular weight=212.2)

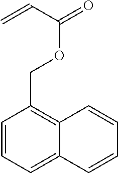 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

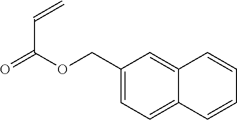 [SMILES: C=CC(=O)OCc1ccc2ccccc2c1]

DPhPA indicated by the formula below (OP=2.38, boiling point=354.5° C., 80° C. vapor pressure=0.0022 mmHg, molecular weight=266.3)

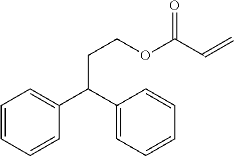 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

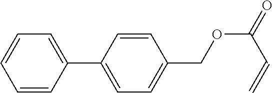 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

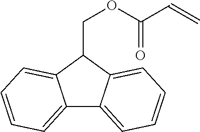 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

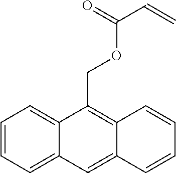 [SMILES: C=CC(=O)OCc1c2ccccc2cc2ccccc12]

DNaMA indicated by the formula below (OP=2.00, boiling point=489.4° C., 80° C. vapor pressure <0.0001 mmHg, molecular weight=338.4)

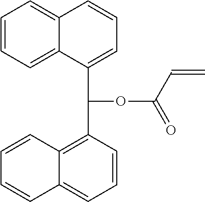 [SMILES: C=CC(=O)OC(c1cccc2ccccc12)c1cccc2ccccc12]

BPh44DA indicated by the formula below (OP=2.63, boiling point=444° C., 80° C. vapor pressure <0.0001 mmHg, molecular weight=322.3)

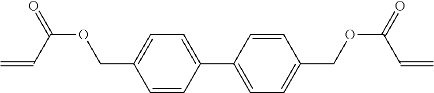 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure <0.0001 mmHg, molecular weight=322.3)

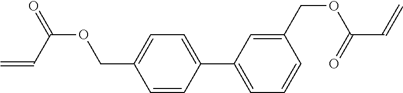 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure <0.0001 mmHg, molecular weight=322.3)

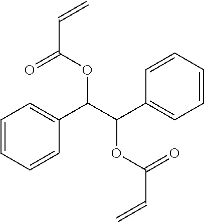 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure <0.0001 mmHg, molecular weight=364.4)

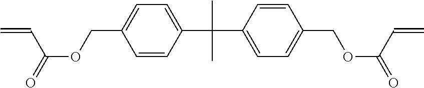 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure <0.0001 mmHg, molecular weight=296.3)

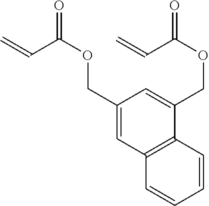 [SMILES: C=CC(=O)OCc1cc(COC(=O)C=C)c2ccccc2c1]

Formula below (a-1-1) (OP=2.40, boiling point=333.4° C., 80° C. vapor pressure=0.0181 mmHg, molecular weight=199.2)

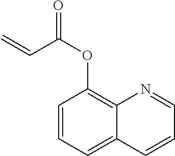

Formula below (a1-1-2) (OP=2.40, boiling point=333.4° C., 80° C. vapor pressure=0.0181 mmHg, molecular weight=199.2)

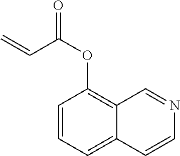

Formula below (a1-1-3) (OP=1.86, boiling point=369.5° C., 80° C. vapor pressure=0.0053 mmHg, molecular weight=193.3)

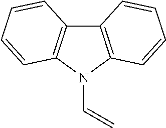

Formula below (a1-1-4) (OP=2.85, boiling point=438.8° C., 80° C. vapor pressure <0.0001 mmHg, molecular weight=296.3)

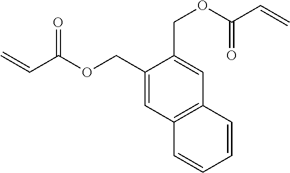 [SMILES: C=CC(=O)OCc1cc2ccccc2cc1COC(=O)C=C]

Formula below (a1-1-5) (OP=2.71, boiling point=438.8° C., 80° C. vapor pressure <0.0001 mmHg, molecular weight=296.3)

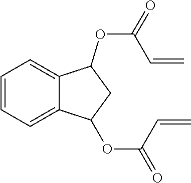 [SMILES: C=CC(=O)OC1CC(OC(=O)C=C)c2ccccc21]

Formula below (a1-1-6) (OP=2.87, boiling point=421.0° C., 80° C. vapor pressure <0.0001 mmHg, molecular weight=338.4)

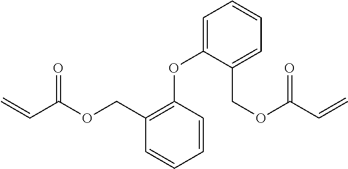 [SMILES: C=CC(=O)OCc1ccccc1Oc1ccccc1COC(=O)C=C]

Formula below (a1-1-7) (OP=2.87, boiling point=465.2° C., 80° C. vapor pressure <0.0001 mmHg, molecular weight=338.4)

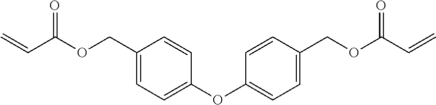 [SMILES: C=CC(=O)OCc1ccc(Oc2ccc(COC(=O)C=C)cc2)cc1]

Formula below (a1-1-8) (OP=2.68, boiling point=465.7° C., 80° C. vapor pressure <0.0001 mmHg, molecular weight=364.4)

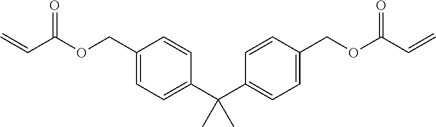 [SMILES: C=CC(=O)OCc1ccc(C(C)(C)c2ccc(COC(=O)C=C)cc2)cc1]

Formula below (a1-1-9) (OP=2.50, boiling point=433.1° C., 80° C. vapor pressure <0.0001 mmHg, molecular weight=320.3)

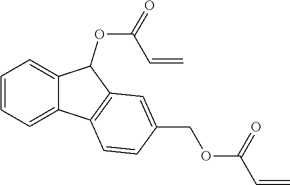 [SMILES: C=CC(=O)OCc1ccc2c(c1)C(OC(=O)C=C)c1ccccc1-2]

Formula below (a1-1-10) (OP=2.64, boiling point=468.1° C., 80° C. vapor pressure <0.0001 mmHg, molecular weight=326.4)

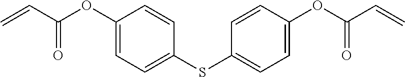 [SMILES: C=CC(=O)Oc1ccc(Sc2ccc(OC(=O)C=C)cc2)cc1]

Formula below (a1-1-11) (OP=3.25, boiling point=553.4° C., 80° C. vapor pressure <0.0001 mmHg, molecular weight=358.4)

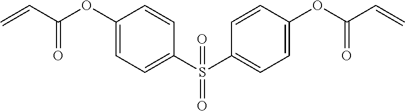 [SMILES: C=CC(=O)Oc1ccc(S(=O)(=O)c2ccc(OC(=O)C=C)cc2)cc1]

Formula below (a1-1-12) (OP=2.63, boiling point=443.9° C., 80° C. vapor pressure <0.0001 mmHg, molecular weight=322.4)

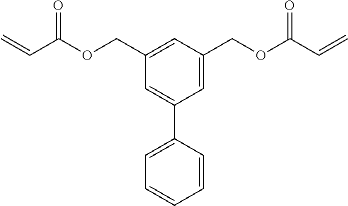 [SMILES: C=CC(=O)OCc1cc(COC(=O)C=C)cc(-c2ccccc2)c1]

Formula below (a1-1-13) (OP=2.89, boiling point=509.3° C., 80° C. vapor pressure <0.0001 mmHg, molecular weight=406.4)

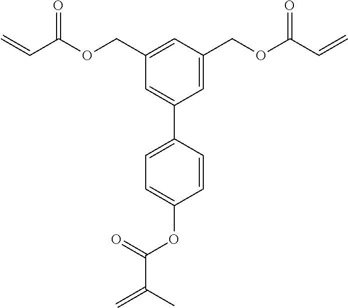 [SMILES: C=CC(=O)OCc1cc(COC(=O)C=C)cc(-c2ccc(OC(=O)C(=C)C)cc2)c1]

Formula below (a1-1-14) (OP=2.63, boiling point=450.0° C., 80° C. vapor pressure <0.0001 mmHg, molecular weight=322.4)

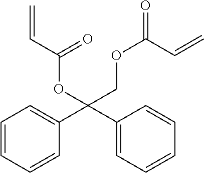 [SMILES: C=CC(=O)OCC(OC(=O)C=C)(c1ccccc1)c1ccccc1]

Formula below (a1-1-15) (OP=3.00, boiling point=476.5° C., 80° C. vapor pressure <0.0001 mmHg, molecular weight=366.4)

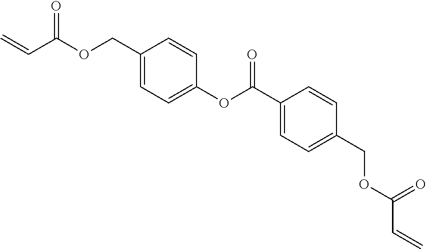 [SMILES: C=CC(=O)OCc1ccc(OC(=O)c2ccc(COC(=O)C=C)cc2)cc1]

Formula below (a1-1-16) (OP=2.68, boiling point=447.4° C., 80° C. vapor pressure <0.0001 mmHg, molecular weight=364.4)

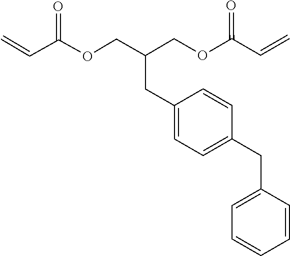 [SMILES: C=CC(=O)OCC(COC(=O)C=C)Cc1ccc(Cc2ccccc2)cc1]

Formula below (a1-1-17) (OP=2.36, boiling point=543.8° C., 80° C. vapor pressure<0.0001 mmHg, molecular weight=398.5)

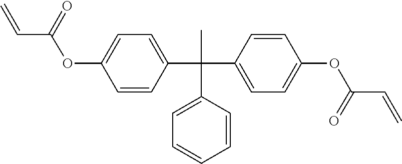 [SMILES: C=CC(=O)Oc1ccc(C(C)(c2ccccc2)c2ccc(OC(=O)C=C)cc2)cc1]

Formula below (a1-1-18) (OP=3.27, boiling point=526.9° C., 80° C. vapor pressure <0.0001 mmHg, molecular weight=396.4)

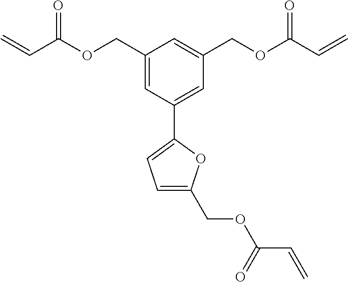 [SMILES: C=CC(=O)OCc1cc(COC(=O)C=C)cc(-c2ccc(COC(=O)C=C)o2)c1]

Formula below (a1-1-19) (OP=2.71, boiling point=333.7° C., 80° C. vapor pressure=0.0302 mmHg, molecular weight=244.3)

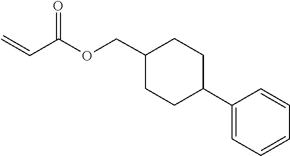 [SMILES: C=CC(=O)OCC1CCC(c2ccccc2)CC1]

Formula below (a1-1-20) (OP=2.73, boiling point=333.7° C., 80° C. vapor pressure=0.0134 mmHg, molecular weight=258.3)

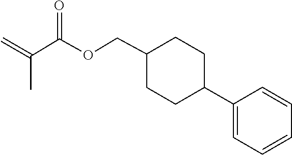 [SMILES: C=C(C)C(=O)OCC1CCC(c2ccccc2)CC1]

Formula below (a1-1-21) (OP=2.71, boiling point=319.2° C., 80° C. vapor pressure=0.0566 mmHg, molecular weight=262.3)

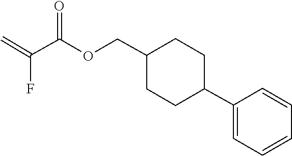 [SMILES: C=C(F)C(=O)OCC1CCC(c2ccccc2)CC1]

Formula below (a1-1-22) (OP=2.71, boiling point=336.9° C., 80° C. vapor pressure=0.0055 mmHg, molecular weight=244.3)

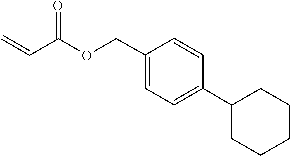 [SMILES: C=CC(=O)OCc1ccc(C2CCCCC2)cc1]

Formula below (a1-1-23) (OP=3.00, boiling point=370.9° C., 80° C. vapor pressure=0.0021 mmHg, molecular weight=274.4)

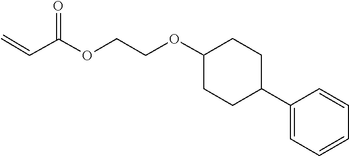 [SMILES: C=CC(=O)OCCOC1CCC(c2ccccc2)CC1]

Formula below (a1-1-24) (OP=3.00, boiling point=376.4° C., 80° C. vapor pressure=0.0005 mmHg, molecular weight=274.4)

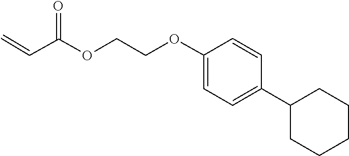 [SMILES: C=CC(=O)OCCOc1ccc(C2CCCCC2)cc1]

Formula below (a1-1-25) (OP=3.00, boiling point=379.4° C., 80° C. vapor pressure=0.0002 mmHg, molecular weight=288.4)

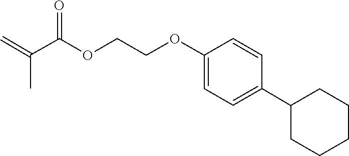 [SMILES: C=C(C)C(=O)OCCOc1ccc(C2CCCCC2)cc1]

Formula below (a1-1-26) (OP=2.33, boiling point=360.8° C., 80° C. vapor pressure=0.0006 mmHg, molecular weight=252.3)

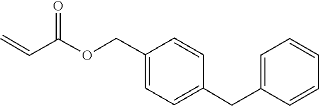 [SMILES: C=CC(=O)OCc1ccc(Cc2ccccc2)cc1]

Formula below (a1-1-27) (OP=2.54, boiling point=371.5° C., 80° C. vapor pressure=0.0003 mmHg, molecular weight=254.3)

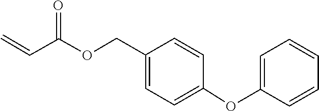 [SMILES: C=CC(=O)OCc1ccc(Oc2ccccc2)cc1]

Formula below (a1-1-28) (OP=2.57, boiling point=381.2° C., 80° C. vapor pressure=0.0001 mmHg, molecular weight=268.3)

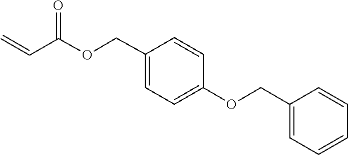 [SMILES: C=CC(=O)OCc1ccc(OCc2ccccc2)cc1]

Formula below (a1-1-29) (OP=2.57, boiling point=381.8° C., 80° C. vapor pressure=0.0004 mmHg, molecular weight=268.3)

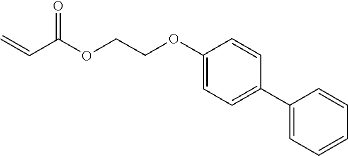 [SMILES: C=CC(=O)OCCOc1ccc(-c2ccccc2)cc1]

Formula below (a1-1-30) (OP=2.50, boiling point=487.4° C., 80° C. vapor pressure <0.0001 mmHg, molecular weight=374.4)

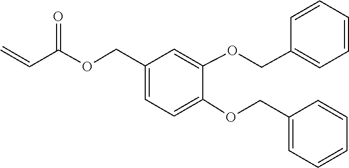 [SMILES: C=CC(=O)OCc1ccc(OCc2ccccc2)c(OCc2ccccc2)c1]

Formula below (a1-1-31) (OP=2.67, boiling point=417.2° C., 80° C. vapor pressure <0.0001 mmHg, molecular weight=268.3)

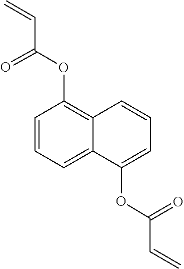 [SMILES: C=CC(=O)Oc1cccc2c(OC(=O)C=C)cccc12]

Formula below (a1-1-32) (OP=2.67, boiling point=417.2° C., 80° C. vapor pressure <0.0001 mmHg, molecular weight=268.3)

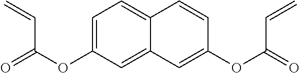 [SMILES: C=CC(=O)Oc1ccc2ccc(OC(=O)C=C)cc2c1]

Formula below (a1-1-33) (OP=2.67, boiling point=417.2° C., 80° C. vapor pressure <0.0001 mmHg, molecular weight=268.3)

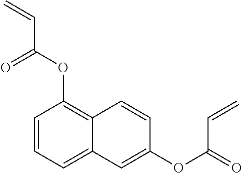 [SMILES: C=CC(=O)Oc1ccc2c(OC(=O)C=C)cccc2c1]

Formula below (a1-1-34) (OP=2.67, boiling point=417.2° C., 80° C. vapor pressure <0.0001 mmHg, molecular weight=268.3)

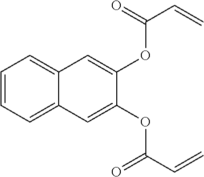 [SMILES: C=CC(=O)Oc1cc2ccccc2cc1OC(=O)C=C]

Formula below (a1-1-35) (OP=2.71, boiling point=438.8° C., 80° C. vapor pressure <0.0001 mmHg, molecular weight=296.3)

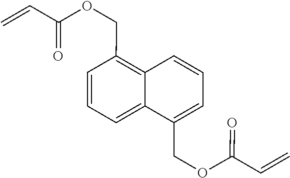 [SMILES: C=CC(=O)OCc1cccc2c(COC(=O)C=C)cccc12]

<Compound (a1-2): Polymerizable Compound Containing at Least Si Atoms>

The polymerizable compound (a1) according to the present disclosure may contain a polymerizable compound (a1-2) containing at least Si atoms. Furthermore, if the polymerizable compound (a1) contains the polymerizable compound (a1-2), the curable composition (A′) from which the solvent (d1) is removed preferably contains Si atoms of 10 wt % or more with respect to the whole curable composition (A).

As an example of the polymerizable compound (a1-2) containing at least Si atoms, it may have a linear structure or a branched structure. For example, as cyclic siloxane compounds, the following structures can be used. An example of a polymerizable functional group in a group Q having a polymerizable functional group is a radical polymerizable functional group. Practical examples of the radical polymerizable functional group are a (meth)acrylic group, a (meth)acrylamide group, a vinylbenzene group, an allyl ether group, a vinylether group, and a maleimide group. The group Q having a polymerizable functional group need only be a group having the above-described polymerizable functional group.

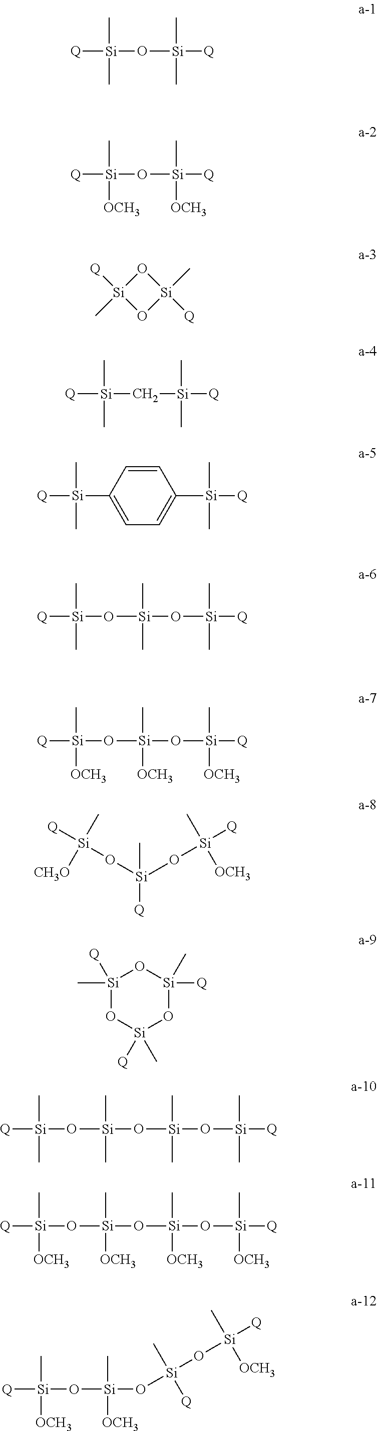

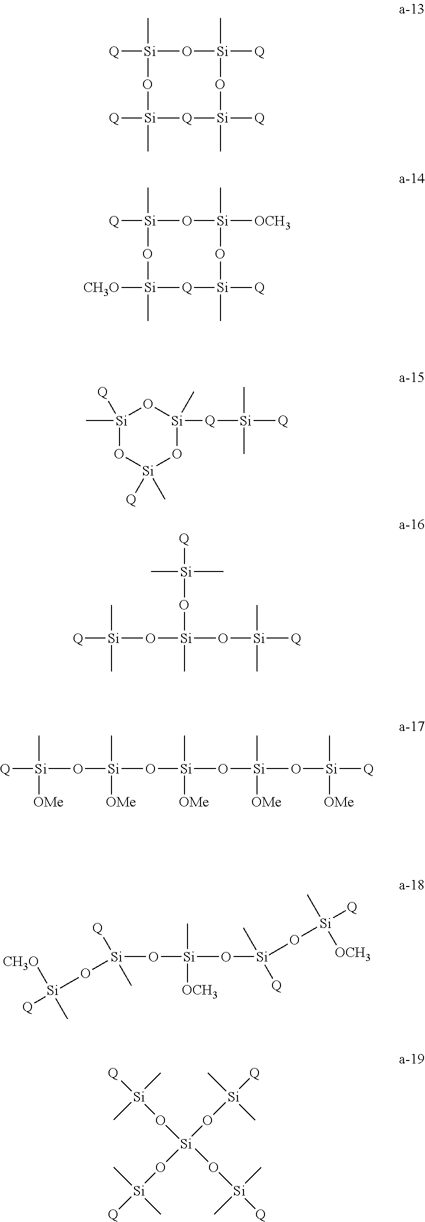

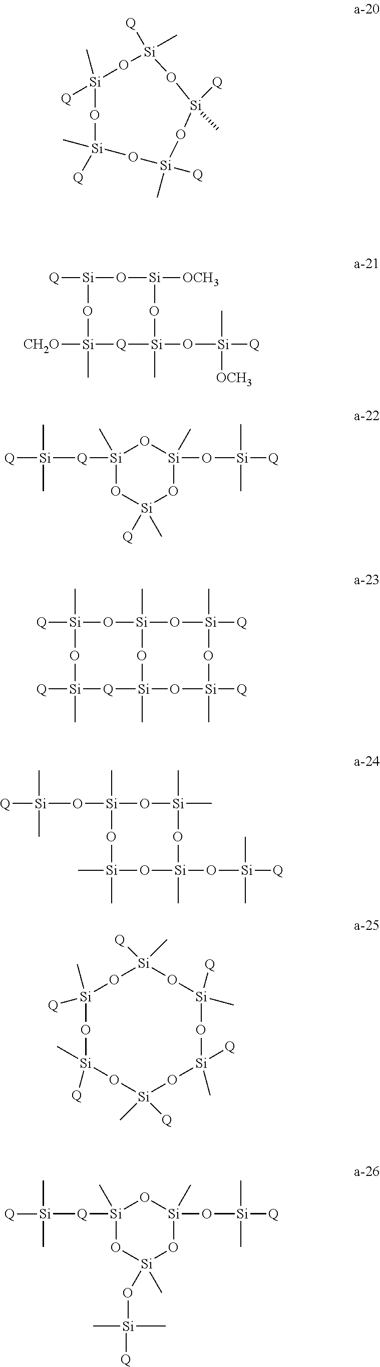

Other examples of the polymerizable compound (a1-2) are a silsesquioxane skeleton as indicated by chemical formula (I) below and a silicone skeleton as indicated by chemical formula (II). In chemical formula (I), m+n=8 (8≥m≥1), and R₁ is a bivalent organic group. Additionally, in chemical formula (II), A, B, R₂, and R₃ are independently an alkyl group, a cycloalkyl group, an alkoxy group, a phenyl group, and hydroxyl group whose carbon number is 1 to 6, t is an integer of 1 to 3, and at least one of A and B is a polymerizable functional group.

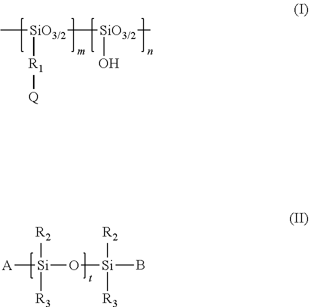

An example of a polymerizable functional group in groups Q, A, and B having a polymerizable functional group is a radical polymerizable functional group. Detailed examples of the radical polymerizable functional group are a (meth)acrylate-based compound, a (meth)acrylamide-based compound, a vinylbenzene-based compound, an aryl ether-based compound, a vinyl ether-based compound, and a maleimide-based compound. The group Q having a polymerizable functional group can be a group having the above-described polymerizable functional group.

A silicon-containing (meth)acrylate-based compound is a compound having one or more acryloyl groups or methacryloyl groups. Examples of a silicon-containing monofunctional (meth)acrylate-based compound having one acryloyl group or methacryloyl group are as follows, but the compound is not limited to these examples.
(2-acryloylethoxy)trimethylsilane,
N-(3-acryloyl-2-hydroxypropyl)-3-aminopropyltriethoxysilane,
acryloxymethyltrimethoxysilane,
(acryloxymethyl)phenethyltrimethoxysilane,
acryloxymethyltrimethylsilane,
(3-acryloxypropyl)dimethylmethoxysilane,
(3-acryloxypropyl)methylbis(trimethylsiloxy)silane,
(3-acryloxypropyl)methyldichlorosilane,
(3-acryloxypropyl)methyldiethoxysilane,
(3-acryloxypropyl)methyldimethoxysilane,
(3-acryloxypropyl)trichlorosilane,
(3-acryloxypropyl)trimethoxysilane,
(3-acryloxypropyl)tris(trimethylsiloxy)silane,
acryloxytriisopropylsilane,
acryloxytrimethylsilane,
methacryloxymethyltrimethoxysilane,
O-(methacryloxyethoxy)carbamoylpropylmethyldimethoxysilane,
(methacryloxymethyl)bis(trimethylsiloxy)methylsilane,
N-(3-methacryloyl-2-hydroxypropyl)-3-aminopropyltriethoxysilane,
(methacryloxymethyl)methyldimethoxysilane,
(methacryloxymethyl)methyldiethoxysilane,
methacryloxymethyltriethoxysilane,
methacryloxypropyltrimethoxysilane,
methacryloylpropyltriisopropoxysilane,
O-(methacryloxyethyl)-N-(triethoxysilylpropyl) carbamate,
methacryloxypropylmethyldimethoxysilane,
methacryloxypropylmethyldiethoxysilane,
methacryloxypropyldimethylmethoxysilane,
methacryloxypropyldimethylethoxysilane,
(methacryloxymethyl)dimethylethoxysilane,
methacryloxypropyltriethoxysilane,
methacryloxypropylsilatrane,
methacryloxypentamethyldisiloxane,
(methacryloxymethyl)phenyldimethylsilane,
methacryloxytrimethylsilane,
methacryloxymethyltrimethylsilane,
(3-methacryloxy-2-hydroxypropoxypropyl)methyl bis(trimethylsiloxy)silane,
methacryloxypropylpentamethyldisiloxane,
O-(methacryloxyethyl)-3-[bis(trimethylsiloxy)methylsilyl]propylcarbamate,
methacryloxymethyltris(trimethylsiloxy)silane,
methacryloxyethoxytrimethylsilane,
(3-methacryloxy-2-hydroxypropoxypropyl)methyl bis(trimethylsiloxy)silane,
methacryloxypropyltris(vinyldimethylsiloxy)silane,
methacryloxypropyltris(trimethylsiloxy)silane,
3-methacryloxypropyltriacetoxysilane,
methacryloxypropylmethyldichlorosilane,
methacryloxypropyltrichlorosilane,
3-methacryloxypropylbis(trimethylsiloxy)methylsilane,
3-methacroloxypropyldimethylchlorosilane,
O-methacryloxy(polyethyleneoxy)trimethylsilane,
poly(methacryloxypropylsilsesquioxane),
methacryloxypropylheptaisobutyl-T8-silsesquioxane, and
methacryloxypropyltris(trimethylsiloxy)silane

Examples of the commercially available products of the above-described silicon-containing monofunctional (meth)acrylic compounds are as follows, but the products are not limited to these examples.

SIA0160.0, SIA0180.0, SIA0182.0, SIA0184.0, SIA0186.0, SIA0190.0, SIA0194.0, SIA0196.0, SIA0197.0, SIA0198.0, SIA0199.0, SIA0200.0, SIA0200.A1, SIA0210.0, SIA0315.0, SIA0320.0, SIM6483.0, SIM6487.5, SIM6480.76, SIM6481.2, SIM6486.1, SIM6481.1, SIM6481.46, SIM6481.43, SIM6482.0, SIM6487.4, SIM6487.35, SIM6480.8, SIM6486.9, SIM6486.8, SIM6486.5, SIM6486.4, SIM6481.3, SIM6487.3, SIM6487.1, SIM6487.6, SIM6486.14, SIM6481.48, SIM6481.5, SIM6491.0, SIM6485.6, SIM6481.15, SIM6487.0, SIM6481.05, SIM6485.8, SIM6481.0, SIM6487.4LI, SIM6481.16, SIM6487.8, SIM6487.6HP, SIM6487.17, SIM6486.7, SIM6487.2, SIM6486.0, SIM6486.2, SIM6487.6-06, SIM6487.6-20, SIM6485.9, SST-R8C42, SLT-3R01, and SIM6486.65 (manufactured by GELEST), and TM-0701T, FM-0711, FM-0721, and FM-0725 (manufactured by JNC)

A silicon-containing (meth)acrylamide-based compound is a compound having one or more acrylamide groups or methacrylamide groups. Examples of a silicon-containing monofunctional (meth)acrylamide-based compound having one acrylamide group or methacrylamide group are as follows, but the compound is not limited to these examples.

3-acrylamidopropyltrimethoxysilane, and 3-acrylamidopropyltris(trimethylsiloxy)silane

Examples of the commercially available products of the above-described silicon-containing monofunctional (meth)acrylamide compounds are as follows, but the products are not limited to these examples.

SIA0146.0, and SIA0150.0 (manufactured by GELEST)

Examples of a polyfunctional (meth)acrylate-based compound having two or more acryloyl groups or methacryloyl groups are as follows, but the compound is not limited to these examples.
linear polydimethylsiloxane modified on both ends with acryloxypropyl groups, linear polydimethylsiloxane modified on both ends with methacryloxypropyl groups,
cyclic siloxane modified with multiple acryloxypropyl groups,
cyclic siloxane modified with multiple methacryloxypropyl groups,
silsesquioxane modified with multiple acryloxypropyl groups, and
silsesquioxane modified with multiple methacryloxypropyl groups

Examples of the commercially available products of the above-described silicon-containing polyfunctional (meth)acrylate compounds are as follows, but the products are not limited to these examples.
SIA0200.2, SIA0200.3, SIM6487.42, DMS-R11, DMS-R05, DMS-R22, DMS-R18, DMS-R31 (manufactured by GELEST),
FM-7711, FM-7721, FM-7725 (manufactured by JNC),
X-22-2445 (manufactured by Shin-Etsu Chemical), and
AC-SQ TA-100, MAC-SQ TM-100, AC-SQ SI-20, MAC-SQ SI-20 (manufactured by TOAGOSEI)

Also, according to, for example, “Ultraviolet curable branched siloxanes as low-k dielectrics for imprint lithography” by Ogawa et al., the following can be synthesized and/or obtained.
linear modified polydimethylsiloxane with methacryloxypropyl groups on both ends (MA-Si-12), 8-membered ring siloxane modified with four methacryloxypropyl groups (8-ring), and 10-membered ring siloxane modified with five methacryloxypropyl groups (10-ring).

The blending ratio of the component (a1) in the curable composition (A) is preferably 40 wt % or more and 99 wt % or less with respect to the sum of the component (a1), a component (b1) (to be described later), and a component (c1) (to be described later), that is, the total mass of all the components except the solvent (d1). The blending ratio is more preferably 50 wt % or more and 95 wt % or less, and further preferably 60 wt % or more and 90 wt % or less. When the blending ratio of the component (a1) is 40 wt % or more, the mechanical strength of the cured film of the curable composition increases. Also, when the blending ratio of the component (a1) is 99 wt % or less, it is possible to increase the blending ratios of the components (b1) and (c1), and obtain characteristics such as a high photopolymerization rate. At least a part of the component (a1) including one or more types of polymerizable compounds can be polymers having a polymerizable functional group. A polymer like this preferably contains at least a cyclic structure such as an aromatic structure, an aromatic heterocyclic structure, or an alicyclic structure. For example, the polymer preferably contains at least one of constituent units represented by structures (1) to (6) below:

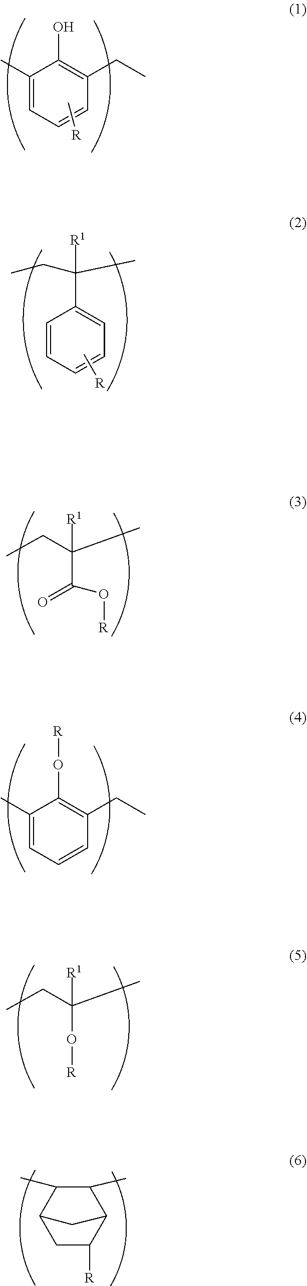

In the structures (1) to (6), a substituent group R is a substituent group containing partial structures each independently containing an aromatic ring, and R¹ is a hydrogen atom or a methyl group. In this specification, in constituent units represented by the structures (1) to (6), a portion other than R is the main chain of a specific polymer. The formula weight of the substituent group R is 80 or more, preferably 100 or more, more preferably 130 or more, and further preferably 150 or more. The upper limit of the formula weight of the substituent group R is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, when the weight-average molecular weight is set at the above-described upper limit or less, the solubility to the solvent increases, and the flowability of discretely arranged droplets is maintained because the viscosity is not too high. This makes it possible to further improve the flatness of the liquid film surface. Note that the weight-average molecular weight (Mw) in the present disclosure is a molecular weight measured by gel permeation chromatography (GPC) unless it is specifically stated otherwise.

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness.

When adding the polymer having the polymerizable functional group as at least a part of the component (a1), the blending ratio can freely be set as long as the blending ratio falls within the range of the viscosity regulation to be described later. For example, the blending ratio to the total mass of all the components except for the solvent (d1) is preferably 0.1 wt % or more and 60 wt % or less, more preferably 1 wt % or more and 50 wt % or less, and further preferably 10 wt % or more and 40 wt % or less. When the blending ratio of the polymer having the polymerizable functional group is set at 0.1 wt % or more, it is possible to improve the heat resistance, the dry etching resistance, the mechanical strength, and the low volatility. Also, when the blending ratio of the polymer having the polymerizable functional group is set at 60 wt % or less, it is possible to make the blending ratio fall within the range of the upper limit regulation of the viscosity (to be described later).

### <Component (b1): Photopolymerization Initiator>

The component (b1) is a photopolymerization initiator. In this specification, the photopolymerization initiator is a compound that senses light having a predetermined wavelength and generates a polymerization factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation). The component (b1) can be formed by only one type of a photopolymerization initiator, and can also be formed by a plurality of types of photopolymerization initiators.

Examples of the radical generator are as follows, but the radical generator is not limited to these examples.

2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-2-(O-benzoyloxime)], ethanone, 1-[9-ethyl-6-(2-methylbenzoyl)-9H-carbazole-3-yl]-, and 1-(0-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of commercially available products of the above-described radical generators are as follows, but the products are not limited to these examples.

Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b1) is preferably an acylphosphine oxide-based polymerization initiator. Note that of the above-described radical generators, the acylphosphine oxide-based polymerization initiators are as follows.

Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the component (b1) in the curable composition (A) is preferably 0.1 wt % or more and 50 wt % or less with respect to the sum of the component (a1), the component (b1), and a component (c1) (to be described later), that is, the total mass of all the components except for the solvent (d1). Also, the blending ratio of the component (b1) in the curable composition (A) is more preferably 0.1 wt % or more and 20 wt % or less, and further preferably 1 wt % or more and 20 wt % or less with respect to the total mass of all the components except for the solvent (d1). When the blending ratio of the component (b1) is set at 0.1 wt % or more, the curing rate of the composition increases, so the reaction efficiency can be improved. Also, when the blending ratio of the component (b1) is set at 50 wt % or less, a cured film having mechanical strength to some extent can be obtained.

### <Component (c1): Nonpolymerizable Compound>

In addition to the components (a1) and (b1) described above, the curable composition (A) of the present disclosure can further contain a nonpolymerizable compound as the component (c1) within a range that does not impair the effect of the present disclosure. An example of the component (c1) is a compound that does not contain a polymerizable functional group such as a (meth)acryloyl group, and does not have the ability to sense light having a predetermined wavelength and generate the polymerization factor (radical) described previously. Examples of the nonpolymerizable compound are a sensitizer, a hydrogen donor, a surfactant (c1), an antioxidant, a polymer component, and other additives. The component (c1) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b1). The “interaction” herein mentioned is energy transfer or electron transfer from the sensitizing dye in the excited state to the photopolymerization initiator as the component (b1). Practical examples of the sensitizing dye are as follows, but the sensitizing dye is not limited to these examples.

An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiation radical generated from the photopolymerization initiator as the component (b1) or a radical at a polymerization growth end, and generates a radical having higher reactivity. The hydrogen donor is preferably added when the photopolymerization initiator as the component (b1) is a photo-radical generator.

Practical examples of the hydrogen donor as described above are as follows, but the hydrogen donor is not limited to these examples.

Amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester.

It is possible to use one type of a hydrogen donor alone, or to use two or more types of hydrogen donors by mixing them. The hydrogen donor can also have a function as a sensitizer.

In the present disclosure, the contact angle of the curable composition (A) to an adhesion layer can be controlled to a desired value by adding the surfactant (c1). In particular, a fluorine-based surfactant to be described later exhibits the pinning effect on a three-phase interface between the substrate, the curable composition, and air, and can make the contact angle large.

The surfactant (c1) also functions as an internal mold release agent that reduces the interface bonding force between a mold and the curable composition, that is, reducing the mold release force in a mold release step (to be described later). In this specification, “internal” means that the mold release agent is added to the curable composition in advance before a curable composition arranging step. As the surfactant (c1), it is possible to use surfactants such as a silicone-based surfactant, a fluorine-based surfactant, and a hydrocarbon-based surfactant.

In the present disclosure, however, the addition amount of the surfactant (c1) is limited, as will be described later. Note that the surfactant (c1) according to the present disclosure is not polymerizable. It is possible to use one type of surfactant (c1) alone, or to use two or more types of surfactants (c1) by mixing them.

The fluorine-based surfactant includes the following.

A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H,1H,2H,2H-perfluorooctylether.

It is also possible to use a commercially available product as the fluorine-based surfactant. Examples of the commercially available product of the fluorine-based surfactant are as follows.

MEGAFACE® F-444, TF-2066, TF-2067, and TF-2068, and DEO-15 (abbreviation) (manufactured by DIC); Fluorad FC-430 and FC-431 (manufactured by Sumitomo 3M); Surflon® S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE® DS-401, DS-403, and DS-451 (manufactured by DAIKIN); and FUTAGENT® 250, 251, 222F, and 208G (manufactured by NEOS).

The surfactant (c1) can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows.

A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of polyalkylene oxide are as follows.

Polyethylene glycol, polypropylene glycol, their mono or dimethyl ether, mono or dioctyl ether, mono or dinonyl ether, and mono or didecyl ether, monoadipate, monooleate, monostearate, and monosuccinate.

A commercially available product can also be used as the alkyl alcohol polyalkylene oxide adduct. Examples of the commercially available product of the alkyl alcohol polyalkylene oxide adduct are as follows.

Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

Also, the surfactant (c1) may be a silicone-based surfactant. Examples of a silicone-based surfactant are as follows. For example, product name SI-10 series (manufactured by TAKEMOTO OIL & FAT), MEGAFACE Paintad 31 (manufactured by DIC), and KP-341 (manufactured by Shin-Etsu Chemical) can be used.

The surfactant (c1) may be a surfactant containing at least both fluorine atoms and silicon atoms. Examples of the surfactant containing both fluorine atoms and silicon atoms are as follows.

Product names X-70-090, X-70-091, X-70-092, X-70-093 (manufactured by Shin-Etsu Chemical), and product names MEGAFACE R-08 and XRB-4 (manufactured by DIC)

The blending ratio of the component (c1) in the curable composition (A) except for the surfactant is preferably 0.01 wt % or more and 50 wt % or less with respect to the sum of the components (a1), (b1), and (c1), that is, the total mass of all the components except for the solvent (d1). The blending ratio of the component (c1) in the curable composition (A) except for the surfactant is more preferably 0.01 wt % or more and 50 wt % or less, and further preferably 0.01 wt % or more and 20 wt % or less with respect to the total mass of all the components except for the solvent (d1). When the blending ratio of the component (c1) except for the surfactant is set at 50 wt % or less, a cured film having mechanical strength to some extent can be obtained.

### <Component (d1): Solvent>

The curable composition of the present disclosure contains a solvent having a boiling point of 100° C. or more and less than 250° C. at normal pressure as the solvent (d1). The component (d1) is a solvent that dissolves the components (a1) and (b1). Examples are an alcohol-based solvent, a ketone-based solvent, an ether-based solvent, and a nitrogen-containing solvent. As the component (d1), it is possible to use one type of a component alone, or to use two or more types of components by combining them. The boiling point at normal pressure of the component (d1) is 100° C. or more, preferably 140° C. or more, and particularly preferably 150° C. or more. The boiling point at normal pressure of the component (d1) is less than 250° C., and preferably less than 200° C. If the boiling point of the component (d1) at normal pressure is less than 100° C., the volatilization speed in the waiting step to be described later is too high. For this reason, the component (d1) may volatilize before the droplets of the curable composition (A) bond to each other, and the droplets of the curable composition (A) may not bond to each other. Also, if the boiling point at normal pressure of the component (d1) is 250° C. or more, it is possible that the volatilization of the solvent (d1) is insufficient in the waiting step to be described later, so the component (d1) remains in the cured product of the curable composition (A). Here, if the component (d1) includes one or more types of solvents, the boiling point of each of the one or more types of solvents at normal pressure is preferably 100° C. or more and less than 250° C. (for example, 100° C. or more and less than 200° C.).

Examples of the alcohol-based solvent are as follows.

Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.

Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows.

Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy)ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.

Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.

N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples of the solvent are as follows.

Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate. Note that (ethyl)isocyanurate di(meth)acrylate is also favorable.

In the present disclosure, a favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-heptanone, γ-butyrolactone, and ethyl lactate.

In the present disclosure, a polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.

Cyclohexyl acrylate (boiling point=198° C.), benzyl acrylate (boiling point=229° C.), isobornyl acrylate (boiling point=245° C.), tetrahydrofurfuryl acrylate (boiling point=202° C.), trimethylcyclohexyl acrylate (boiling point=232° C.), isooctyl acrylate (217° C.), n-octyl acrylate (boiling point=228° C.), ethoxyethoxyethyl acrylate (boiling point=230° C.), divinylbenzene (boiling point=193° C.), 1,3-diisopropenylbenzene (boiling point=218° C.), styrene (boiling point=145° C.), and α-methylstyrene (boiling point=165° C.).

In the present disclosure, when the whole of the curable composition (A) is 100 vol %, the content of the solvent (d1) can be 5 vol % or more and 95 vol % or less, preferably 15 vol % or more and 85 vol % or less, and further preferably 40 vol % or more and 80 vol % or less. The whole of the curable composition (A) indicates the total volume of the polymerizable compound (a1), the photopolymerization initiator (b1), and the solvent (d1). For example, the content of the solvent (d1) is 40 vol % or more and 85 vol % or less. If the content of the solvent (d1) is smaller than 5 vol %, it is difficult to obtain a thin film after the solvent (d1) volatilized under the condition that a practically continuous liquid film can be obtained. On the other hand, if the content of the solvent (d1) is larger than 95 vol %, it is difficult to obtain a thick film after the solvent (d1 volatilized even when droplets are closely dropped by an inkjet method.

### <Temperature When Blending Curable Composition>

When preparing the curable composition (A) of the present disclosure, at least the components (a1), (b1), and (d1) are mixed and dissolved under a predetermined temperature condition. More specifically, the predetermined temperature condition is 0° C. or more and 100° C. or less. Note that the same applies to a case in which the curable composition (A) contains the component (c1).

### <Viscosity of Curable Composition>

The curable composition (A) of the present disclosure is a liquid. This is so because droplets of the curable composition (A) are discretely dropped on a substrate by an inkjet method. The viscosity of the curable composition (A) according to the present disclosure is 1.3 mPa·s or more and 60 mPa·s or less at 23° C. and at 1 atm, preferably 2 mPa·s or more and 30 mPa·s or less, and more preferably 5 mPa·s or more and 15 mPa·s or less. If the viscosity of the curable composition (A) is smaller than 2 mPa·s, the discharge property of droplets by an inkjet method may be unstable. Also, if the viscosity of the curable composition (A) is larger than 60 mPa·s, it is difficult to form droplets having a volume of about 1.0 to 3.0 μL favorable in the present disclosure.

The viscosity in a state in which the solvent (d1) volatilized from the curable composition (A), that is, the viscosity of a mixture of components except for the solvent (d1) of the curable composition (A) at 23° C. and at 1 atm is 30 mPa·s or more and 10,000 mPa·s or less. The viscosity of the mixture of components except for the solvent (d1) of the curable composition (A) at 23° C. and at 1 atm is preferably 90 mPa·s or more and 2,000 mPa·s or less, for example, 120 mPa·s or more and 1,000 mPa·s or less. Also, the viscosity of the mixture of components except for the solvent (d1) of the curable composition (A) at 23° C. and at 1 atm is further preferably 150 mPa·s or more and 500 mPa·s or less. When the viscosity of the components except for the solvent (d2) of the curable composition (A) is set to 1,000 mPa·s or less, spreading and filling are rapidly completed when bringing the curable composition (A) into contact with a mold.

Accordingly, the use of the curable composition (A) of the present disclosure makes it possible to perform an imprinting process at high throughput, and suppress pattern defects caused by insufficient filling. Also, when the viscosity of components except for the solvent (d1) of the curable composition (A) is set to 1 mPa·s or more, it is possible to prevent an unnecessary flow of droplets of the curable composition (A′) after the solvent (d1) volatilized. Furthermore, when bringing the curable composition (A) into contact with a mold, the curable composition (A) does not easily flow out from the end portions of the mold.

### <Contact Angle of Curable Composition>

Concerning the contact angle of the curable composition (A), the inventors found that when the contact angle of the curable composition (A) to an adhesion layer or a silicon substrate is 1.8[°] or less, the droplets of the curable composition bond to each other on the substrate, and a continuous liquid film can be formed.

In this embodiment, the contact angle of a composition in a state in which the solvent (d1) is removed from the curable composition (A) to the adhesion layer or the silicon substrate is 11[°] or more and 19[°] or less. The inventors found that when the contact angle of the composition in a state in which the solvent (component (d1)) is removed from the curable composition (A) to the surface of the adhesion layer or the silicon substrate is 11[°] or more, the pinning effect to the spread of the droplets is obtained. This can stop the spread of the droplets on the substrate in a desired size and suppress the extrusion amount of the curable composition. In addition, when the contact angle of the composition in a state in which the solvent (component (d1)) is removed from the curable composition (A) to the surface of the adhesion layer or the silicon substrate is 19[°] or less, shrinkage of the liquid film formed on the substrate can be suppressed.

### <Impurities Mixed in Curable Composition>

The curable composition (A) of the present disclosure preferably contains impurities as little as possible. Note that impurities mean components other than the components (a1), (b1), (c1), and (d1) described above. Therefore, the curable composition (A) of the present disclosure is favorably a composition obtained through a refining step. A refining step like this is preferably filtration using a filter.

As this filtration using a filter, it is favorable to mix the components (a1), (b1), and (c1) described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition can be removed through the refining step as described above. Consequently, it is possible to prevent impurities mixed in the curable composition from causing pattern defects by forming unexpected unevenness on a cured film obtained after the curable composition is cured.

Note that when using the curable composition of the present disclosure in order to fabricate a semiconductor integrated circuit, it is favorable to avoid mixing of impurities (metal impurities) containing metal atoms in the curable composition as much as possible so as not to obstruct the operation of a product. The concentration of the metal impurities contained in the curable composition is preferably 10 ppm or less, and more preferably 100 ppb or less.

### <Glass Transition Temperature of Curable Composition>

If a glass transition temperature is much higher than the temperature at the time of mold release, the cured product at the time of mold release exhibits a firm glass state, that is, a high mechanical strength, and therefore, pattern collapse or breakage due to impact of mold release hardly occurs. Hence, when executing the mold release step at room temperature, the glass transition temperature of the cured product (after curing of the polymerizable compound (a1)) is preferably 70° C. or more, more preferably 100° C. or more, and particularly preferably 150° C. or more.

As a method of measuring the glass transition temperature of the cured product (photocured product), a method of performing measurement using differential scanning calorimetry (DSC) or a dynamic viscoelasticity measuring apparatus can be applied. For example, consider a case where the glass transition temperature is measured using DSC. In this case, a line obtained by extending the baseline of the DSC curve of a cured product on the low temperature side (a DSC curve portion in a temperature region where neither transition nor reaction occurs in a test piece) to the high temperature side and a tangent drawn at a point where the gradient of the curve of the stepwise change portion of glass transition is maximum are obtained. From the intersection between the line and the tangent, an extrapolated glass transition start temperature (Tig) is obtained, and this can be obtained as the glass transition temperature. An example of a major apparatus is STA-6000 (manufactured by Perkin Eimer). On the other hand, when measuring the glass transition temperature using a dynamic viscoelasticity measuring apparatus, a temperature at which the loss sine (tan δ) of the cured product is maximum is defined as the glass transition temperature. An example of a major apparatus for measuring dynamic viscoelasticity is MCR301 (manufactured by Anton Paar).

### [Layer Forming Composition]

A layer forming composition according to the present disclosure is a composition configured to form an adhesion layer between the base material (substrate) and the curable composition.

The layer forming composition contains at least a compound (a2) having at least one functional group bonded to the base material and at least one polymerizable functional group, a cross-linker (b2), and a solvent (d2). Here, “making the base material and the curable composition adhere” can be defined as a state in which, in the mold release step, the base material and the cured film are bonded via the adhesion layer with a strength stronger than a force for separating a mold from the cured film of the curable composition. As will be described later, the mold release step is a step of separating the mold from the cured film of the curable composition formed on the base material in imprint processing.

The layer forming composition according to this embodiment is particularly preferably used when forming a cured film (cured product) of the curable composition on the base material. Also, a multilayered body including the base material and the adhesion layer formed by the layer forming composition according to this embodiment can preferably be used as a base material on which the curable composition is arranged (supplied) to obtain a cured film. Also, the layer forming composition according to this embodiment can be used as an adhesion layer forming composition for imprint, and is particularly useful as an adhesion layer forming composition for photo-nanoimprint. Here, in this embodiment, an example in which a photocurable composition having a property of curing upon light irradiation is used as the curable composition will be described. However, the curable composition is not limited to the photocurable composition, and a thermally curable composition having a property of curing upon heating may be used.

Components of the layer forming composition according to this embodiment will be described below in detail. The layer forming composition according to this embodiment contains the compound (a2), the cross-linker (b2), and the solvent (d2), as described above.

<Compound (a2)>

The compound (a2) has at least one functional group to be bonded to the base material, and at least one polymerizable functional group to be bonded to the curable composition. Here, “functional group to be bonded” indicates a functional group that causes a chemical bond such as a covalent bond, an ionic bond, a hydrogen bond, or an intermolecular force. If the whole layer forming composition is defined as 100 mass %, the compound (a2) is contained at a ratio less than 1 mass %. As for the type of the compound (a2) usable in this embodiment, known compounds can widely be employed, and the type is not particularly limited.

The compound (a2) according to this embodiment has, in one molecule, at least one of a hydroxyl group, a carboxyl group, a thiol group, an amino group, an epoxy group, and a (block)isocyanate group. Examples of the compound (a2) are a compound having an ethylenically unsaturated bond containing group, a compound having an epoxy group, and a compound having a vinyl ether group.

Detailed examples of the compound (a2) having an ethylenically unsaturated bond containing group are methyl (meth)acrylate, ethyl (meth)acrylate, butyl (meth)acrylate, N-vinyl-pyrrolidinone, 2-acryloyloxyethyl phthalate, 2-acryloyloxy 2-hydroxyethyl phthalate, 2-acryloyloxyethyl hexahydrophthalate, 2-acryloyloxypropyl phthalate, 2-ethyl-2-butyl propanediol acrylate, 2-ethylhexyl (meth)acrylate, 2-ethylhexylcarbitol (meth)acrylate, 2-hydroxybutyl (meth)acrylate, 2-hydroxyethyl (meth)acrylate, 2-hydroxypropyl (meth)acrylate, 4-hydroxybutyl (meth)acrylate, acrylic acid dimer, benzyl (meth)acrylate, 1- or 2-naphthyl (meth)acrylate, butoxyethyl (meth)acrylate, cetyl (meth)acrylate, ethylene oxide-modified (to be referred to as “EO” hereinafter) cresol (meth)acrylate, dipropylene glycol (meth)acrylate, ethoxylated phenyl (meth)acrylate, isooctyl (meth)acrylate, cyclohexyl (meth)acrylate, isobornyl (meth)acrylate, dicyclopentanyl (meth)acrylate, dicyclopentanyloxyethyl (meth)acrylate, isomyristyl (meth)acrylate, lauryl (meth)acrylate, methoxydipropylene glycol (meth)acrylate, methoxytripropylene glycol (meth)acrylate, methoxypolyethylene glycol (meth)acrylate, methoxytriethylene glycol (meth)acrylate, neopentyl glycol benzoate (meth)acrylate, nonyl phenoxypolyethylene glycol (meth)acrylate, nonyl phenoxypolypropylene glycol (meth)acrylate, octyl (meth)acrylate, paracumyl phenoxyethylene glycol (meth)acrylate, epichlorohydrin (to be referred to as “ECH” hereinafter)-modified phenoxyacrylate, phenoxyethyl (meth)acrylate, phenoxydiethylene glycol (meth)acrylate, phenoxyhexaethylene glycol (meth)acrylate, phenoxytetraethylene glycol (meth)acrylate, polyethylene glycol (meth)acrylate, polyethylene glycol-polypropylene glycol (meth)acrylate, polypropylene glycol (meth)acrylate, stearyl (meth)acrylate, EO-modified succinic acid (meth)acrylate, tribromophenyl (meth)acrylate, EO-modified tribromophenyl (meth)acrylate, tridodecyl (meth)acrylate, p-isopropenylphenol, N-vinylpyrrolidone, N-vinylcaprolactam, diethylene glycol monoethyl ether (meth)acrylate, dimethyloldicyclopentane di(meth)acrylate, di(meth)acryloyl isocyanurate, 1,3-butylene glycol di(meth)acrylate, 1,4-butanediol di(meth)acrylate, EO-modified 1,6-hexanediol di(meth)acrylate, ECH-modified 1,6-hexanediol di(meth)acrylate, allyloxypolyethylene glycol acrylate, 1,9-nonanediol di(meth)acrylate, EO-modified bisphenol A di(meth)acrylate, PO-modifed bisphenol A di(meth)acrylate, modified bisphenol A di(meth)acrylate, EO-modified bisphenol F di(meth)acrylate, ECH-modified hexahydrophthalic acid diacrylate, hydroxypivalic acid neopentyl glycol di(meth)acrylate, neopentyl glycol di(meth)acrylate, EO-modifed neopentyl glycol diacrylate, propylene oxide (to be referred to as “PO” hereinafter)-modified neopentyl glycol diacrylate, caprolactone-modified hydroxypivalate neopentyl glycol, stearic acid-modified pentaerythritol di(meth)acrylate, ECH-modified phthalic acid di(meth)acrylate, poly(ethylene glycol-tetramethylene glycol) di(meth)acrylate, poly(propylene glycol-tetramethylene glycol) di(meth)acrylate, polyester (di)acrylate, polyethylene glycol di(meth)acrylate, polypropylene glycol di(meth)acrylate, ECH-modified propylene glycol di(meth)acrylate, silicone di(meth)acrylate, triethylene glycol di(meth)acrylate, tetraethylene glycol di(meth)acrylate, dimethyloltricyclodecane di(meth)acrylate, neopentyl glycol-modified trimethylolpropane di(meth)acrylate, tripropylene glycol di(meth)acrylate, EO-modified tripropylene glycol di(meth)acrylate, triglycerol di(meth)acrylate, dipropylene glycol di(meth)acrylate, divinyl ethylene urea, divinyl propylene urea, o-,m-,p-xylylene di(meth)acrylate, 1,3-adamantane diacrylate, norbornane dimethanol di(meth)acrylate, tricyclodecane dimethanol di(meth)acrylate, ECH-modified glycerol tri(meth)acrylate, EO-modified glycerol tri(meth)acrylate, PO-modified glycerol tri(meth)acrylate, pentaerythritol triacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, caprolactone-modified dipentaerythritol hexa(meth)acrylate, dipentaerythritol hydroxypenta (meth)acrylate, alkyl-modified dipentaerythritol penta (meth)acrylate, dipentaerythritol poly(meth)acrylate, alkyl-modified dipentaerythritol tri(meth)acrylate, ditrimethylolpropane tetra(meth)acrylate, pentaerythritol ethoxytetra(meth)acrylate, and pentaerythritol tetra(meth)acrylate.

Examples of the compound (a2) having an epoxy group are polyglycidyl ethers of polyether polyols obtained by adding one type or two types of alkylene oxides to aliphatic polyhydric alcohols such as bisphenol A diglycidyl ether, bisphenol F diglycidyl ether, bisphenol S diglycidyl ether, brominated Bisphenol A diglycidyl ether, brominated Bisphenol F diglycidyl ether, brominated bisphenol S diglycidyl ether, hydrogenated Bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ether, ethylene glycol, propylene glycol, and glycerin, diglycidyl esters of aliphatic long-chain dibasic acids, monoglycidyl ethers of aliphatic higher alcohols, phenol, cresol, butyl phenol, or monoglycidyl ethers of polyether alcohol obtained by adding alkylene oxide to these, and blycidyl esters of higher fatty acids.

Examples of the compound (a2) having a vinyl ether group are 2-ethylhexyl vinyl ether, butanediol-1,4-divinyl ether, diethylene glycol monovinyl ether, diethylene glycol monovinyl ether, ethylene glycol divinyl ether, triethylene glycol divinyl ether, 1,2-propanediol divinyl ether, 1,3-propanediol divinyl ether, 1,3-butanediol divinyl ether, 1,4-butanediol divinyl ether, tetramethylene glycol divinyl ether, neopentyl glycol divinyl ether, trimethylolpropane trivinyl ether, trimethylolethane tri vinyl ether, hexanediol divinyl ether, tetraethylene glycol divinyl ether, pentaerythritol divinyl ether, pentaerythritol trivinyl ether, pentaerythritol tetra vinyl ether, sorbitol tetra vinyl ether, sorbitol penta-vinyl ether, ethylene glycol diethylene vinyl ether, triethylene glycol diethylene vinyl ether, ethylene glycol dipropylene vinyl ether, triethylene glycol diethylene vinyl ether, trimethylolpropane triethylene vinyl ether, trimethylolpropane diethylene vinyl ether, pentaerythritol diethylene vinyl ether, pentaerythritol triethylene vinyl ether, pentaerythritol tetraethylene vinyl ether, 1,1,1-tris[4-(2-vinyloxyethoxy)phenyl]ethane, bisphenol A divinyloxyethyl ether.

As an example, a poly(meth)acrylate compound having an ethylenically unsaturated group (P) and a hydrophilic group (Q) is preferable. Examples of the ethylenically unsaturated group (P) are a (meth)acryloyloxy group, a (meth)acryloylamino group, a maleimide group, an allyl group, and a vinyl group. Note that in this specification, a (meth)acryloyl group means an acryloyl group or a methacryloyl group having an alcohol residue equivalent to that. Examples of the hydrophilic group (Q) are an alcoholic hydroxyl group, a carboxyl group, a phenolic hydroxyl group, an ether group (preferably, a polyoxyalkylene group), an amino group, an amide group, an imide group, a ureido group, a urethane group, a cyano group, a sulfonamide group, a lactone group, and a cyclocarbonate group. If the hydrophilic group is a urethane group, a group adjacent to the urethane group preferably exists as an oxygen atom, for example, “—O—C(═O)—NH—” in a resin.

A poly(meth)acrylate compound (acrylic resin) may include a repeating unit including the ethylenically unsaturated group (P) and a repeating unit including the hydrophilic group (Q) in the same repeating unit or different repeating units. However, the poly(meth)acrylate compound (acrylic resin) preferably includes these repeating units at a ratio of 20 to 100 mol %. Also, the poly(meth)acrylate compound (acrylic resin) may include another repeating unit that includes neither the ethylenically unsaturated group (P) nor the hydrophilic group (Q), and the ratio of the other repeating units is preferably 50 mol % or less in the acrylic resin.

The poly(meth)acrylate compound (acrylic resin) preferably includes repeating units represented by general formulas (I) and (II) below.

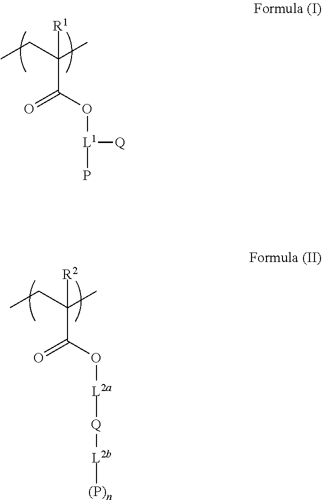

(In general formulas (I) and (II), R¹ and R² each indicate a hydrogen atom, a methyl group, or a hydroxymethyl group. L¹ indicates a trivalent linking group, L^{2a} indicates a single bond or a bivalent linking group, and L²b indicates a single bond, a bivalent linking group, or a trivalent linking group. P indicates an ethylenically unsaturated group, Q indicates a hydrophilic group, and n is 1 or 2).

R¹ and R² independently indicate a hydrogen atom, a methyl group, or a hydroxymethyl group. As R¹ and R², the hydrogen atom or the methyl group is preferable, and the methyl group is more preferable.

L¹ indicates a trivalent linking group. The trivalent linking group is an aliphatic group, an alicyclic groups, an aromatic groups, or a trivalent group obtained by combining these, and may include an ester bond, an ether bond, a sulfide bond, and a nitrogen atom. The carbon number of the trivalent linking group is preferably 1 to 9.

L²a indicates a single bond or a bivalent linking group. The bivalent linking group is an alkylene group, a cycloalkylene group, an arylene group, or a bivalent group obtained by combining these, and may include an ester bond, an ether bond, and a sulfide bond. The carbon number of the bivalent linking group is preferably 1 to 8.

L^{2b} indicates a single bond, a bivalent linking group, or a trivalent linking group. The bivalent linking group indicated by L^{2b} is the same as the bivalent linking group indicated by L^{2a}, and the preferable range is also the same. The trivalent linking group indicated by L^{2b} is the same as the trivalent linking group indicated by L¹, and the preferable range is also the same.

P indicates an ethylenically unsaturated group. The ethylenically unsaturated group indicated by P is the same as the ethylenically unsaturated group exemplified above, and the preferable ethylenically unsaturated group is also the same. Also, Q indicates a hydrophilic group. The hydrophilic group indicated by Q is the same as the hydrophilic group exemplified above, and the preferable hydrophilic group is also the same.

n is 1 or 2, and is preferably 1.

Note that L¹, L^{2a}, and L^{2b} do not include an ethylenically unsaturated group and a hydrophilic group.

The poly(meth)acrylate compound (acrylic resin) may further include repeating units represented by general formula (III) and/or general formula (IV) below.

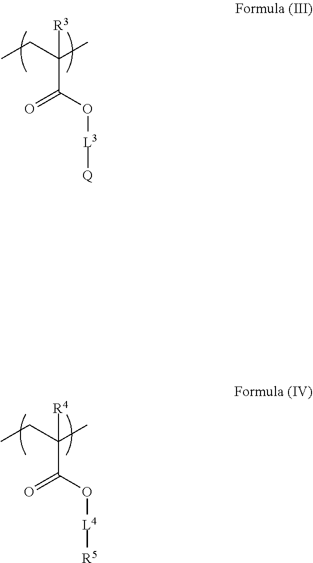

(In general formulas (III) and (IV), R³ and R⁴ each indicate a hydrogen atom, a methyl group, or a hydroxymethyl group. L³ and L⁴ each indicate a single bond or a bivalent linking group. Q indicates a hydrophilic group. R⁵ indicates an aliphatic group with 1 to 12 carbon atoms, an alicyclic group with 3 to 12 carbon atoms, or an aromatic group with 6 to 12 carbon atoms).

R³ and R⁴ each indicate a hydrogen atom, a methyl group, or a hydroxymethyl group. As R³ and R⁴, the hydrogen atom or the methyl group is preferable, and the methyl group is more preferable.

L³ and L⁴ each indicate a single bond or a bivalent linking group. The bivalent linking group indicated by each of L³ and L⁴ is the same as the bivalent linking group indicated by L²a in general formula (I), and the preferable range is also the same.

Q indicates a hydrophilic group. The hydrophilic group indicated by Q is the same as the hydrophilic group exemplified above, and the preferable hydrophilic group is also the same.

R⁵ indicates an aliphatic group with 1 to 12 carbon atoms, an alicyclic group, or an aromatic group. Examples of the aliphatic group with 1 to 12 carbon atoms are alkyl groups with 1 to 12 carbon atoms (for example, a methyl group, an ethyl group, a propyl group, an isopropyl group, a butyl group, an isobutyl group, a t-butyl group, a pentyl group, an isopentyl group, a neopentyl group, a hexyl group, a heptyl group, an octyl group, a 2-ethylhexyl group, a 3,3,5-trimethylhexyl group, an isooctyl group, a nonyl group, an isononyl group, a decyl group, an isodecyl group, an undecyl group, and a dodecyl group).

Examples of the alicyclic group with 3 to 12 carbon atoms are cycloalkyl groups with 3 to 12 carbon atoms (for example, a cyclopentyl group, a cyclohexyl group, a norbornyl group, an isobornyl group, an adamantyl group, and a tricyclodecanyl group). Examples of the aromatic group with 6 to 12 carbon atoms are a phenyl group, a naphthyl group, and a biphenyl group. In particular, the phenyl group and the naphthyl group are preferable. The aliphatic group, the alicyclic group, and the aromatic group may have a substituent group.

Detailed examples of an acrylic resin usable in this embodiment will be described below. Note that in the following detailed example, x indicates 0 to 50 mol %, y indicates 0 to 50 mol %, and z indicates 20 to 100 mol %.

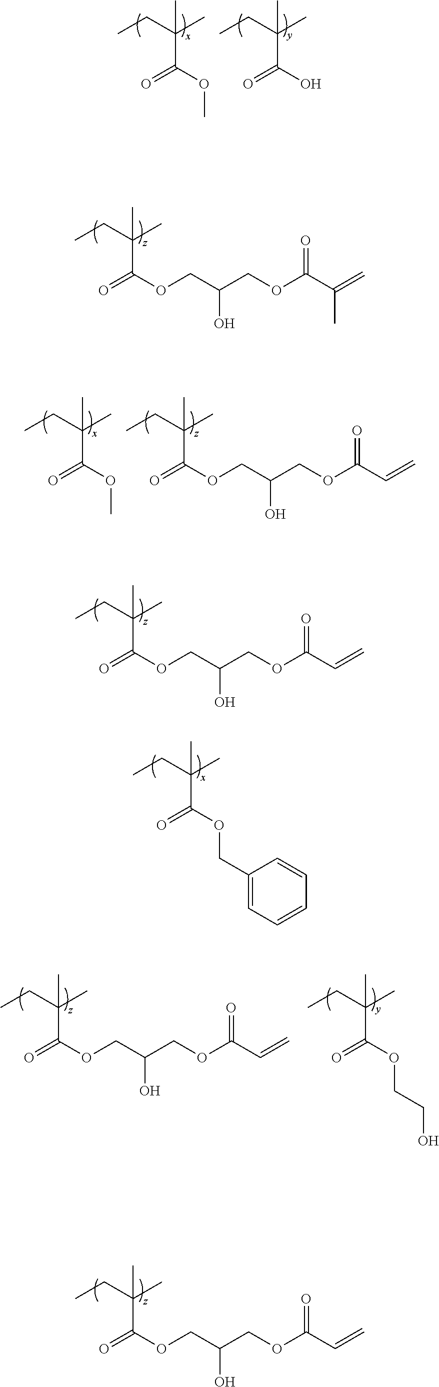

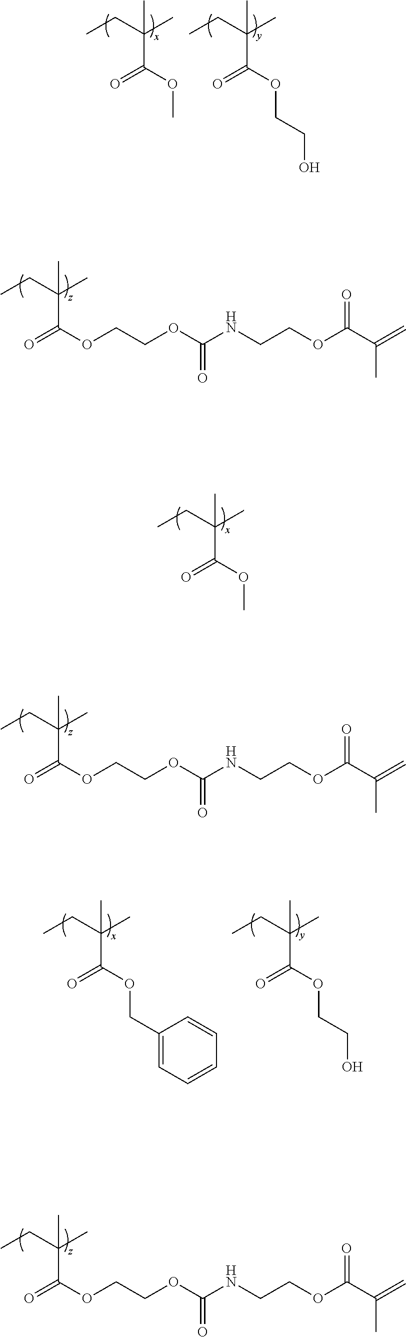

Another example of the compound (a2) usable in this embodiment is a compound whose main chain includes an aromatic ring. An example of the compound (a2) including an aromatic ring is a compound whose main chain is formed by an aromatic ring and an alkylene group, and the main chain has a structure in which benzene rings and methylene rings are alternately bonded. The compound (a2) preferably has a reactive group in the side chain, more preferably has an (meth)acryloyl group in the side chain, and more preferably has an acryloyl group in the side chain.

The compound (a2) whose main chain includes an aromatic ring is preferably a polymer mainly containing a structural unit represented by general formula (a2-1) below, and more preferably a polymer in which the content of the structural unit represented by general formula (a2-1) below is 90 mol % or more.

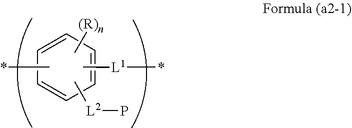

(In general formula (a2-1), R is an alkyl group, L¹ and L² are each a bivalent linking group, and P is a polymerizable group. n is an integer of 0 to 3).

R is preferably an alkyl group with 1 to 5 carbon atoms, and more preferably a methyl group. L1 is preferably an alkylene group, more preferably an alkylene group with 1 to 3 carbon atoms, and more preferably “—CH₂—”. L² is preferably “—CH₂—”, “—O—”, “—CHR (R is a substituent group)-”, and a bivalent linking group formed by combining two or more of these. R is preferably an OH group. P is preferably a (meth)acryloyl group, and more preferably an acryloyl group. n is preferably an integer of 0 to 2, and more preferably 0 or 1.

Still another example of the compound (a2) usable in this embodiment is an epoxy poly(meth)acrylate compound. Also, as the compound (a2), a compound described in, for example, paragraphs [0040] to [0056] of Japanese Patent Laid-Open No. 2009-503139 is usable, and the contents can be incorporated in this specification by reference.

Of the above-described compounds (a2), a compound having a functional group with a high bondability with the base material is preferable. The functional group with a high bondability with the base material is selected from a hydroxyl group, a carboxyl group, a thiol group, an amino group, an epoxy group, and a (block)isocyanate group and the hydroxyl group or the carboxyl group is particularly preferable.

The compound (a2) may be a low-molecular compound or a polymer, and a polymer is preferable. The molecular weight is normally 200 or more and 100,000 or less, preferably 500 or more and 50,000 or less, and further preferably 1,000 or more and 10,000 or less. If the molecular weight of the compound (a2) is 200 or less, it may volatilize in a baking step. If the molecular weight is 100,000 or more, bubbles may remain in a spin coating step.

Note that the compound (a2) may be formed by one type of a compound, or may be formed by a plurality of types of compounds.

<Cross-Linker (b2)>

The cross-linker (b2) according to this embodiment is a compound including, in one molecule, at least a total of five groups of one or both of an alkoxyalkyl group and an alkylol group (to be referred to as “functional groups a” hereinafter).

The functional group a included in the cross-linker (b2) according to this embodiment is a functional group that reacts with a hydroxyl group or a carboxyl group included in the compound (a2) in an adhesion layer forming step to be described later. As a result, a bond is generated between the compound (a2) and the cross-linker (b2). The cross-linker (b2) includes a plurality of functional groups a in one molecule and can therefore generate bonds with a plurality of compounds (a2). When the cross-linker (b2) generates bonds with the plurality of compounds (a2), a structure (crosslinked structure) in which the compounds of the adhesion layer cross-link can be formed.

The reaction between the functional group a included in the cross-linker (b2) according to this embodiment and the hydroxyl group or the carboxyl group included in the compound (a2) preferably occurs in the heating process in the adhesion layer forming step to be described later.

When the adhesion layer having a crosslinked structure is formed, the amount of the liberated unreacted compound (a2) or cross-linker (b2), which is not connected to the base material, can be reduced. Thus, the film strength of the adhesion layer can be improved.

If the unreacted compound (a2) or cross-linker (b2) in a liberated state exists in the adhesion layer, in the arranging step of the curable composition to be described later, these compounds may elute into the curable composition. As a result, the composition of the curable composition changes, and the property of the curable composition thus changes. This may cause, for example, a pattern peeling defect in the cured film obtained by curing the curable composition.

On the other hand, if the layer forming composition according to this embodiment is used, the amount of the liberated unreacted compound (a2) or cross-linker (b2) in the adhesion layer, which is not connected to the base material, can be made much smaller than before. It is therefore possible to greatly suppress elution of the compound (a2) or the cross-linker (b2) into the curable composition in the arranging step of the curable composition. As a result, occurrence of the above-described pattern peeling defect in the cured film can be suppressed.

Also, the functional group a included in the cross-linker (b2) may generate a chemical bond such as a covalent bond, an ionic bond, a hydrogen bond, or an intermolecular force or an interaction with a functional group that exists on the surface of the base material. For example, if a base material including a hydroxyl group such as a silanol group is used as the base material, dealcoholation reaction occurs between the alkoxyalkyl group and the silanol group. As a result, a covalent bond can be formed between the cross-linker (b2) and the base material. This can improve the adhesion between the adhesion layer and the base material.

Furthermore, the cross-linker (b2) is preferably a compound represented by general formula (b2-1) below.

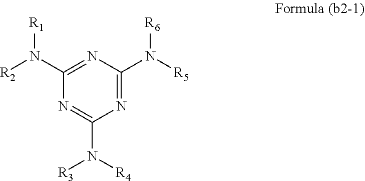

In general formula (b2-1), R₁ to R₆ independently indicate one of a hydrogen atom, an alkyl group, an alkoxyalkyl group, and an alkylol group. However, at least five of R₁ to R₆ are an alkoxyalkyl group or an alkylol group.

The compound represented by general formula (b2-1) above is a derivative of melamine having a triazine ring at the center of the structure. That is, the compound represented by general formula (1) has a structure in which nitrogen atoms are bonded to the 2-, 4-, and 6-positions of 1,3,5-triazine. Also, the compound represented by general formula (1) has five or six functional groups a. That is, the compound represented by general formula (b2-1) above has many functional groups a as compared to urea compounds such as a derivative of glycoluril.

The type of the alkoxyalkyl group or the alkylol group included in the cross-linker (b2) is not particularly limited. As the alkoxyalkyl group, a methoxymethyl group is preferable, and as the alkylol group, a methylol group is preferable. When a functional group with a small formula weight is used as the alkoxyalkyl group or the alkylol group, the crosslinking density per unit mass in the adhesion layer can be improved. As a result, the film strength of the adhesion layer can be improved.

Detailed examples of the cross-linker (b2) are pentamethoxymethylmelamine, hexamethoxymethylmelamine, (hydroxymethyl)pentakis(methoxymethyl)melamine, hexaethoxymethyl melamine, hexabutoxymethyl melamine, pentamethylol melamine, and hexamethylol melamine. The cross-linker (b2) can contain at least one substance selected from these, but the present invention is not limited to this.

As the cross-linker (b2), a urea compound may be applied. Detailed examples of the urea compound are methylated urea cross-linkers such as tetrakis(methoxymethyl)glycoluril, 4,5-dimethoxy-1,3bis(methoxymethyl)imidazolidin-2-one, tetrakis(butoxymethyl)glycoluril, tetrakis(ethoxymethyl)glycoluril, tetrakis(isopropoxymethyl)glycoluril, tetrakis(amyloxymethyl)glycoluril, and tetrakis(hexoxymethyl)glycoluril.

As commercially available urea compounds, NIKALAC MX-270, NIKALAC MX-280, and NIKALAC MX-290 commercially available from SANWA Chemical, Powderlink 1174 commercially available from American Cyanamid Co., and Cymel 1170 commercially available from Cytec Industries can preferably be used.

Monomers of the above-described resins can also be used. Examples are the following compounds and dimethoxymethyl urea.

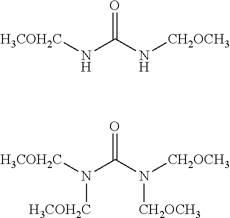

Note that the cross-linker (b2) may be formed by one type of a compound, or may be formed by a plurality of types of compounds.

<Blending Ratio of Compound (a2) and Cross-Linker (b2)>

If the blending ratio of one of the compound (a2) and the cross-linker (b2) in the layer forming composition is extremely small, the crosslinking density of the adhesion layer is low, and the film strength or curability is insufficient. Hence, when the weight fractions of the compound (a2) and the cross-linker (b2) with respect to the total weight of the layer forming composition are defined as a and β, respectively, α:β is preferably 1:9 to 9:1, and more preferably 1:5 to 5:1. That is, α/β is preferably 0.11 or more and 9 or less, and more preferably 0.2 or more and 5 or less. Note that the optimum blending ratio changes depending on the number of functional groups, the molecular weights, and the reactivity of the compound (a2) and the cross-linker (b2). If the blending ratio is substantially set within the above-described range, the curability of the layer forming composition can be improved.

The blending ratio (the sum of α and β) of the compound (a2) and the cross-linker (b2) in the layer forming composition can appropriately be adjusted by the viscosity of the layer forming composition or the target film thickness of the adhesion layer. The sum of α and β is preferably 0.01 or more and 10 or less with respect to the total weight of the layer forming composition, more preferably 0.1 or more and 10 or less, and further preferably 0.1 or more and 7 or less. If the blending ratio of the compound (a2) and the cross-linker (b2) in the layer forming composition is set within the above-described range, the viscosity of the layer forming composition can be lowered, and the film thickness of the formed adhesion layer can be made small.

<Volatile Solvent (d2)>

The layer forming composition according to this embodiment contains the volatile solvent (d2) (to be simply referred to as the “solvent (d2)” hereinafter). If the layer forming composition contains the solvent (d2), the viscosity of the layer forming composition can be lowered. As a result, the applicability of the layer forming composition to the base material can be improved.

As the solvent (d2), a first solvent (d2-1) whose boiling point at normal pressure is 80° C. to 200° C. and a second solvent (d2-2) whose boiling point at normal pressure is 200° C. to 300° C. may be used in mixture. Alternatively, as the solvent (d2), the first solvent (d2-1) may be used alone, or the second solvent (d2-2) may be used alone.

The first solvent (d2-1) is not particularly limited if it is a solvent capable of dissolving the compound (a2) and the cross-linker (b2), and a solvent whose boiling point at normal pressure is 80° C. to 200° C. is preferable. Also, the first solvent (d2-1) is preferably an organic solvent having at least one of a hydroxyl group, an ether structure, an ester structure, and a ketone structure. These solvents are excellent in solubility for the compound (a2) and the cross-linker (b2) and wettability to the base material.

As detailed examples of the solvent usable as the first solvent (d1-1) according to this embodiment, a single solvent selected from alcohol solvents such as n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethyl hexanol, sec-octanol, 2,6-dimethylheptanol-4, sec-undecyl alcohol, phenol, cyclohexanol, methylcyclohexanol, 3,3,5-trimethylcyclohexanol, diacetone alcohol, ethylene glycol, 1,2-propylene glycol, 2-methyl-2,4-pentanediol, and propylene glycol; ether solvents such as n-butyl ether, 2-ethylhexyl ether, dioxane, dimethyldioxane, 2-methoxyethanol, 2-ethoxyethanol, ethylene glycol diethyl ether, 2-n-butoxyethanol, diethylene glycol monomethyl ether, diethylene glycol diethyl ether, 1-n-butoxy-2-propanol, propylene glycol monomethyl ether, propylene glycol monoethyl ether, propylene glycol monopropyl ether, dipropylene glycol monomethyl ether, and 2-methyltetrahydrofuran; ester solvents such as butyl acetate, ethylene glycol monoethyl ether acetate, ethylene glycol monobutyl ether acetate, and propylene glycol monomethyl ether acetate; ketone solvents such as methyl ethyl ketone, methyl-n-propyl ketone, methyl-n-butyl ketone, diethyl ketone, methyl iso-butyl ketone, methyl-n-pentyl ketone, ethyl-n-butyl ketone, methyl-n-hexyl ketone, di-iso-butyl ketone, cyclohexanone, methylcyclohexanone, 2,4-pentanedione, acetonylacetone, diacetone alcohol, and fenthion; and amide solvents such as diethyl carbonate, amyl acetate, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, cyclohexyl acetate, methylcyclohexyl acetate, methyl acetoacetate, ethyl acetoacetate, ethylene glycol acetate monomethyl ether, ethylene glycol acetate monoethyl ether, propylene glycol acetate monomethyl ether, propylene glycol acetate monoethyl ether, glycol diacetate, ethyl propionate, n-butyl propionate, iso-amyl propionate, diethyl oxalate, methyl lactate, ethyl lactate, n-butyl lactate, acetic acid solvents such as diethyl malonate, N-methylformamide, N,N-dimethylformamide, N,N-diethylformamide, N,N-dimethylacetamide, and N-methylpropionamide, or a solvent mixture thereof can be used.

Of these, propylene glycol monomethyl ether acetate or a solution mixture thereof is particularly preferable in the viewpoint of applicability.

The second solvent (d2-2) is not particularly limited if it is a solvent capable of dissolving the compound (a2) and the cross-linker (b2), and a solvent whose boiling point at normal pressure is 200° C. to 300° C. is preferable. Also, the second solvent (d2-2) is preferably an organic solvent having at least one of a hydroxyl group, an ether structure, an ester structure, and a ketone structure. These solvents are excellent in solubility for the compound (a2) and the cross-linker (b2) and wettability to the base material.

As detailed examples of the solvent usable as the second solvent (d2-2) according to this embodiment, a single solvent selected from alcohol solvents such as n-nonyl alcohol, n-decanol, sec-tetradecyl alcohol, benzyl alcohol, phenylmethylcarbinol, 1,3-butylene glycol, 2,4-pentanediol, 2,5-hexanediol, 2-ethyl-1,3-hexanediol, diethylene glycol, triethylene glycol, and tripropylene glycol; ether solvents such as n-hexyl ether, 2-n-hexoxyethanol, 2-phenoxyethanol, 2-(2-ethylbutoxy)ethanol, ethylene glycol dibutyl ether, diethylene glycol monoethyl ether, diethylene glycol mono-n-butyl ether, diethylene glycol di-n-butyl ether, diethylene glycol mono-n-hexyl ether, ethoxytriglycol, 1-phenoxy-2-propanol, dipropylene glycol monopropyl ether, and tripropylene glycol monomethyl ether; ketone solvents such as acetophenone; acetic acid solvents such as γ-butyrolactone, γ-valerolactone, benzyl acetate, n-nonyl acetate, diethylene glycol monoethyl ether acetate, diethylene glycol mono-n-butyl ether acetate, dipropylene glycol monomethyl ether acetate, di-n-butyl oxalate, n-amyl lactate, dimethyl phthalate, and diethyl phthalate; and amide solvents such as acetamide, n-methylacetamide, and n-methylpyrrolidone, or a solvent mixture thereof can be used.

As described above, the solvent (d2) may contain two types of solvents, that is, the first solvent (d2-1) and the second solvent (d2-2). In this case, if the total mass of the first solvent (d2-1) and the second solvent (d2-2) is defined as 100 mass parts, the ratio of the second solvent (d2-2) is preferably 1 to 50 mass parts, more preferably 2 to 40 mass parts, and further preferably 5 to 25 mass parts. If the mass part of the second solvent (d2-2) is set within the above-described range, the in-plane uniformity of the film thickness and the defect density are improved. Note that the solvent (d2) may contain three or more types of solvents.

The blending ratio of the solvent (d2) according to this embodiment in the layer forming composition can appropriately be adjusted by the viscosities or applicabilities of the compound (a2) and the cross-linker (b2) and the film thickness of the adhesion layer to be formed. If the whole layer forming composition is defined as 100 mass %, the blending ratio (content) of the solvent (d2) in the layer forming composition is preferably 70 mass % or more, more preferably 90 mass % or more, and further preferably 95 mass % or more. The higher the blending ratio of the solvent (d2) in the layer forming composition is, the thinner the film thickness of the adhesion layer to be formed can be. For this reason, the adhesion layer forming composition is suitable as an adhesion layer forming composition for imprint. If the blending ratio of the solvent (d2) in the layer forming composition is less than 70 mass %, it may be impossible to obtain sufficient applicability. Note that the upper limit of the blending ratio of the solvent (d2) is not particularly limited, but is preferably 99.9 mass % or less, and more preferably 99.5 mass % or less.

<Another Component (e2)>

In addition to the compound (a2), the cross-linker (b2), and the solvent (d2) described above, the layer forming composition according to this embodiment may contain another additive component (e2) in accordance with various purposes if it does not impair the effect of the present disclosure. As the additive component (e2), a cross-linker, a polymer component, an antioxidant, a polymerization inhibitor, or a surfactant can be used. When the layer forming composition is arranged on the base material and then cured while making the solvent (d2) volatilize by heating, the film thickness of the adhesion layer formed on the base material can be made thin. Hence, the layer forming composition according to this embodiment preferably contains no photopolymerization initiator that is added for the purpose of curing the layer forming composition by light irradiation. This is because if the layer forming composition contains a photopolymerization initiator, photopolymerization may occur in the process of formation of the adhesion layer, the layer forming composition may be cured before the solvent (d2) completely volatilizes, and it may be difficult to reduce the film thickness of the adhesion layer.

### <Viscosity of Adhesion Layer Forming Composition>

The viscosity of the layer forming composition according to this embodiment at 23° C. is preferably 0.5 mPa·s or more and 20 mPa·s or less, more preferably 1 mPa·s or more and 10 mPa·s or less, and further preferably 1 mPa·s or more and 5 mPa·s or less. However, the viscosity of the layer forming composition at 23° C. can change depending on the types of components such as the compound (a2), the cross-linker (b2), the solvent (s2), and the other component (e2) added as needed and the blending ratio.

When the viscosity of the layer forming composition at 23° C. is 20 mPa·s or less, it is possible to improve the applicability of the layer forming composition to the base material and easily adjust the film thickness of the layer forming composition on the base material.

### <Impurities Mixed in Adhesion Layer Forming Composition>

The layer forming composition according to this embodiment preferably contains impurities as little as possible. The impurities here means substances other than the compound (a2), the cross-linker (b2) the solvent (d2), and the other component (e2) added as needed, described above. If the layer forming composition is used for imprint processing, it is particularly preferable that it contains no particles and solid components. Here, the particles typically indicate a gel or solid granular substance having a particle size (diameter) of several nm to several μm. Hence, if the whole layer forming composition is defined as 100 mass %, the content of particles whose particle size is larger than 0.2 μm is preferably 0 mass % or more and less than 3 mass %. Alternatively, if the whole layer forming composition is defined as 100 mass %, the content of particles whose particle size is larger than 0.2 μm is preferably less than 1 particle/mL.

Therefore, the layer forming composition according to this embodiment is favorably obtained through a refining step. A refining step like this is preferably filtration using a filter. More specifically, it is favorable to mix the compound (a2), the cross-linker (b2), the solvent (d2), and the other component (e2) added as needed, described above, and filtrate the mixture by using, for example, a filter having a pore diameter of 0.001 μm or more and 5.0 μm or less. The filtration is preferably performed using a filter having a pore diameter of 0.001 μm or more and 0.2 μm or less. When performing filtration using a filter, it is further favorable to perform the filtration in multiple stages, or to repetitively perform the filtration a plurality of times. It is also possible to re-filtrate a liquid once filtrated through a filter, or perform filtration by using a plurality of filters having different pore diameters. Examples of the filter for use in filtration are filters made of, for example, a polyethylene resin, a polypropylene resin, a fluorine resin, and a nylon resin, but the filter is not particularly limited.

Impurities such as particles mixed in the layer forming composition can be removed through the refining step as described above. It is therefore possible to prevent impurities such as particles from causing unexpected defects in the adhesion layer obtained after the layer forming composition is applied.

Note that when using the layer forming composition in order to fabricate a circuit board such as a semiconductor integrated circuit to be used in a semiconductor element, it is favorable to avoid mixing of impurities (metal impurities) containing metal atoms in the layer forming composition as much as possible. This is to prevent impurities such as a metal from obstructing the operation of the circuit board. In this case, the concentration of the metal impurities contained in the layer forming composition is preferably 10 ppm or less, and more preferably 100 ppb or less.

Hence, the layer forming composition is preferably prepared without coming into contact with a metal in the manufacturing step. That is, when weighing or blending and stirring the raw materials of the compound (a2), the cross-linker (b2), the solvent (d2), and the other component (e2) added as needed, described above, it is preferable not to use a weighing tool or container made of a metal. Also, in the above-described refining step, filtration is preferably performed using a metal impurity removing filter. As the metal impurity removing filter, filters made of cellulose, diatomaceous earth, and an ion-exchange resin can be used, but these are not particularly limited. The metal impurity removing filters are preferably used after washing. As the washing method, washing using pure water, washing using an alcohol, and washing using the layer forming composition are preferably executed in this order.

### [Adhesion Layer Forming Step]

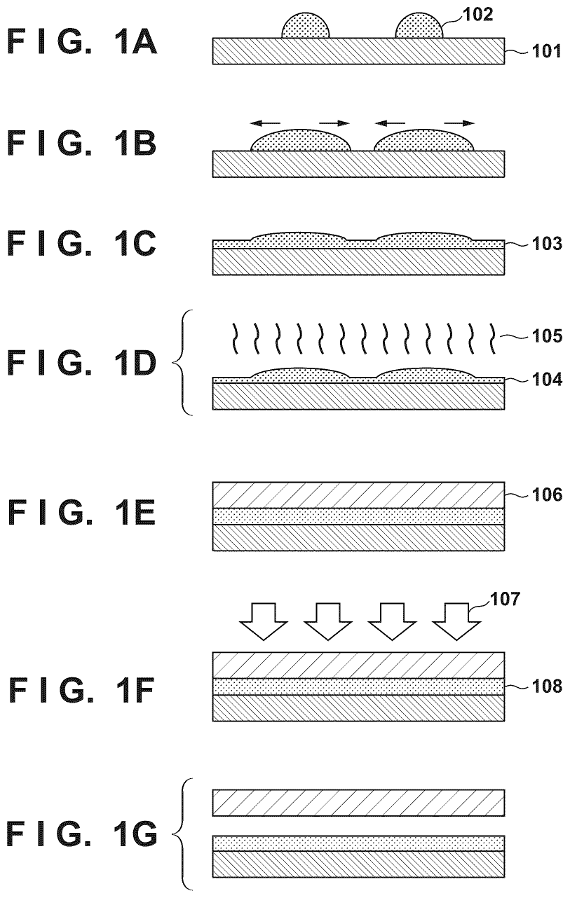

In the adhesion layer forming step, as shown in FIG. 1A, the adhesion layer mainly containing a polymer compound (polymer) is formed on the base material using the above-described layer forming composition.

The base material that is the target to arrange the curable composition is a substrate or a support body, and an arbitrary base material can be selected in accordance with various purposes. For example, a semiconductor device substrate such as a silicon wafer, aluminum, a titanium-tungsten alloy, an aluminum-silicon alloy, an aluminum-copper-silicon alloy, silicon oxide, or silicon nitride, quartz, glass, an optical film, a ceramic material, a deposition film, a magnetic film, a reflection film, a metal base material such as Ni, Cu, Cr, or Fe, paper, a polymer base material such as a polyester film, a polycarbonate film, or a polyimide film, a TFT array base material, an electrode plate of PDP, a plastic base material, a conductive base material of ITO or a metal, or an insulating base material can be used. As the base material, a structure obtained by depositing, on the above-described substrate, one type or a plurality of types of films such as spin-on-glass, an organic matter, a metal, an oxide, and a nitride may be used.

In this embodiment, particularly, as the base material, a base material having a hydroxyl group (OH group) such as a silanol group (SiOH group) on the surface is preferably used. Examples of the base material are a silicon wafer, quartz, and glass. It is considered that when a base material having a hydroxyl group on the surface is used, the hydroxyl group provided on the surface of the base material and the functional group of the compound (a2) of the layer forming composition form a chemical bond by a heat treatment. It is considered that even in a case where the cross-linker (b2) has an alkoxyalkyl group, it forms a chemical bond by a hydroxyl group.

As a method of applying the layer forming composition onto the base material, for example, an inkjet method, a dip coating method, an air knife coating method, a curtain coating method, a wire bar coating method, a gravure coating method, an extrusion coating method, a spin coating method, and a slit scanning method can be used. The spin coating method is particularly favorable among these methods from the viewpoint of applicability, particularly, film thickness evenness.

After the layer forming composition is applied (arranged) onto the base material, the solvent (d2) contained in the layer forming composition is volatized by drying, thereby forming the adhesion layer on the base material. At this time, at the same time as volatilization of the solvent (d2), the base material and the compound (a2) or the cross-linker (b2) are preferably made to react, and the compound (a2) and the cross-linker (b2) are preferably made to react. This forms a bond between the base material and the adhesion layer and forms a bond between the compound (a2) and the cross-linker (b2) in the adhesion layer. Note that it is assumed that a crosslinked structure is formed by the bond of the compound (a2) and the cross-linker (b2).

To effectively perform the volatilization and reaction, it is preferable to perform a heat treatment (baking processing) for the base material to which the layer forming composition is applied. The temperature of the heat treatment can appropriately be selected based on the reactivity between the compound (a2) or the cross-linker (b2) and the base material, the reactivity between the compound (a2) and the cross-linker (b2), and the boiling points of the compound (a2), the cross-linker (b2), the solvent (d2), and the other component (e2). The temperature of the temperature is preferably 70° C. or more and 250° C. or less, more preferably 100° C. or more and 220° C. or less, and further preferably 140° C. or more and 220° C. or less. Also, drying of the solvent (d2), the reaction between the base material and the compound (a2) or the cross-linker (b2), and the crosslinking reaction between the compound (a2) and the cross-linker (b2) may be performed at the same temperature or different temperatures. That is, the reactions may be performed simultaneously or successively.

The film thickness of the adhesion layer formed on the base material by the adhesion layer forming step changes depending on the application purpose, and is, for example, 0.1 nm or more and 100 nm or less, more preferably 0.5 nm or more and 60 nm or less, and further preferably 1 nm or more and 10 nm or less.

When forming the adhesion layer by applying the layer forming composition onto the base material, a second adhesion layer may further be formed on the first adhesion layer using the layer forming composition. This method is called multiple application. Also, the surface of the adhesion layer formed on the base material is preferably as flat as possible. The roughness of the surface is preferably 1 nm or less.

By the adhesion layer forming step, a multilayered body including the base material and the polymer layer (adhesion layer) stacked on the base material can be formed. As described above, the polymer layer takes a crosslinked structure by the reaction between the alkoxyalkyl group or alkylol group of the cross-linker (b2) and the hydroxyl group or carboxyl group of the compound (a2).

### [Pattern Forming Method]

The pattern forming method of the present disclosure will be explained with reference to FIGS. 1A to 1G. The cured film formed by the present disclosure is preferably a film having a pattern with a size of 1 nm or more and 10 mm or less, and more preferably a film having a pattern with a size of 10 nm or more and 100 μm or less. Generally, a film forming method of forming a film having a pattern (uneven structure) of a nano size (1 nm or more and 100 nm or less) by using light is called a photoimprint method. The film forming method of the present disclosure forms a film of a curable composition in a space between a mold and a substrate by using the photoimprint method. However, the curable composition can also be cured by other energy (for example, heat or an electromagnetic wave). A film forming method of the present disclosure can be performed as a method of forming a film having a pattern, that is, as a pattern forming method, and can also be performed as a method of forming a film (for example, a planarization film) having no pattern, that is, as a planarization film forming method.

An example in which the film forming method of the present disclosure is applied to the pattern forming method will be explained below. The pattern forming method includes, for example, a forming step, an arranging step, a waiting step, a contact step, a curing step, and a mold release step (separation step). The forming step is a step of forming an underlayer. The arranging step is a step of discretely arranging droplets of the curable composition (A) on the underlayer. The waiting step is a step of waiting until the droplets of the curable composition (A) bond to each other and the solvent (d1) volatilizes. The contact step is a step of bringing the curable composition (A) and a mold into contact with each other. The curing step is a step of curing the curable composition (A). The mold release step is a step of releasing the mold from the cured film of the curable composition (A). The arranging step is performed after the forming step, the waiting step is performed after the arranging step, the contact step is performed after the waiting step, the curing step is performed after the contact step, and the mold release step is performed after the curing step.

### <Arranging Step>

In the arranging step, as schematically shown in FIG. 1A, droplets 102 of the curable composition (A) are discretely arranged on a substrate 101. In the arranging step, the droplets 102 of the curable composition (A) having a volume of 1.0 pL or more are arranged at a density of 80 droplets/mm² or more. As the substrate 101, a substrate on which an underlayer is stacked can also be used as the substrate 101. In addition, the above-described layer forming composition is preferably formed on the surface of the substrate 101, and the adhesion with respect to the curable composition (A) can be improved by a surface treatment such as a silane coupling treatment, a silazane treatment, or deposition of an organic thin film.

As the silane coupling agent, a known silane coupling agent having an acrylic group can be used. As a method of applying the silane coupling agent, for example, an inkjet method, a dip coating method, an air knife coating method, a curtain coating method, a wire bar coating method, a gravure coating method, an extrusion coating method, a spin coating method, a slit scanning method, or a vapor deposition method can be used. The vapor deposition method is particularly favorable among these methods from the viewpoint of applicability, particularly, film thickness evenness.

Also, as the substrate 101, a silicon substrate that has not undergone a surface treatment can also be used.

An inkjet method is particularly favorable as the arranging method of arranging the droplets 102 of the curable composition (A) on the substrate. It is favorable to arrange the droplets 102 of the curable composition (A) densely on that region of the substrate 101, which faces a region in which recesses forming the pattern of a mold 106 densely exist, and sparsely on that region of the substrate 101, which faces a region in which recesses forming the pattern of the mold 106 sparsely exist. Consequently, a film (residual film) (to be described later) of the curable composition (A) formed on the substrate 101 is controlled to have a uniform thickness regardless of the sparsity and density of the pattern of the mold 106.

An index called an average residual liquid film thickness is defined in order to prescribe the volume of the curable composition (A′) to be arranged. The average residual liquid film thickness is a value obtained by dividing the volume of the curable composition (A′) (except the solvent (d1)) to be arranged in the arranging step by the area of a film formation region of the mold. The volume of the curable composition (A′) (except the solvent (d1)) is the sum total of the volumes of the individual droplets of the curable composition (A) after the solvent (d1) volatilized. According to this definition, the average residual liquid film thickness can be prescribed regardless of the state of unevenness even when the substrate surface is uneven. Here, the average residual liquid film thickness may be understood as a value obtained by dividing the volume of the curable composition (A′) remaining after the waiting step to be described later by the area of the film formation region of the mold, and is preferably 20 nm or less.

### <Waiting Step>

In the present disclosure, the waiting step is provided during time after the arranging step and before the contact step. Here, a value obtained by dividing the total volume of the droplets of the curable composition (A) dropped in one-time pattern formation by the total area of regions (pattern formation regions) in which patterns are formed in one-time pattern formation is defined as an average initial liquid film thickness. In the waiting step, as schematically shown in FIG. 1B, the droplets 102 of the curable composition (A) spread on the substrate 101. Consequently, the whole pattern formation region of the substrate 101 is covered with the curable composition (A).

According to an example to be described later, for example, a case where the solvent (d1) is a highly volatile solvent, the volume ratio of nonvolatile components is 20%, and the droplet pitch is 88 μm, that is, the average initial liquid film thickness is 13 nm or more is selected. In this case, as schematically shown in FIG. 1C, it is indicated by numerical calculation that the droplets of the curable composition (A′) bond to each other on the substrate, and a practically continuous liquid film 103 is formed. Also, this means that the droplets of the curable composition (A) having a volume of 1.0 pL or more are arranged at a density of 130 droplets/mm² or more.

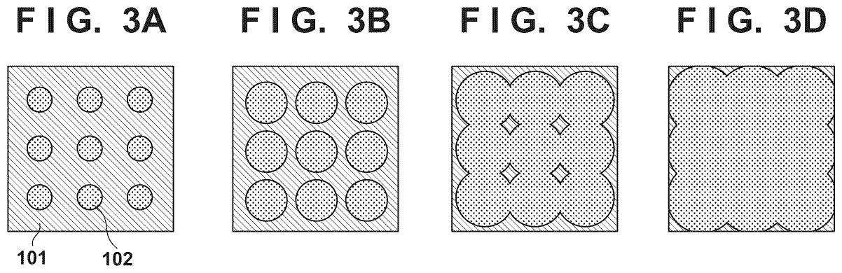

A flow behavior during the waiting step of the droplets of the curable composition (A) arranged on the substrate will be explained with reference to FIGS. 3A to 3D. The droplets 102 of the curable composition (A) are discretely arranged on the substrate 101, as shown in FIG. 3A, and each droplet 102 gradually spreads on the substrate, as shown in FIG. 3B. Then, the droplets of the curable composition (A) on the substrate begin bonding to each other to form a liquid film, as shown in FIG. 3C, and a continuous liquid film is formed (the surface of the substrate 101 is covered with the curable composition (A) and there is no more exposed surface), as shown in FIG. 3D. The state of the curable composition (A) as shown in FIG. 3D is called “a practically continuous liquid film”.

In addition, as schematically shown in FIG. 1D, a solvent 105 (solvent (d1)) contained in a liquid film 104 is volatilized in the waiting step. Assuming that the total weight of the components except for the solvent (d1) is 100 vol %, the residual amount of the solvent (d1) in the liquid film 103 after the waiting step (for example, at the start of the contact step) is preferably 10 vol % or less. If the residual amount of the solvent (d1) is larger than 10 vol %, the mechanical properties of the cured film may deteriorate.

In the waiting step, it is possible to perform a baking step of heating the substrate 101 and the curable composition (A), or ventilate the atmospheric gas around the substrate 101, for the purpose of accelerating the volatilization of the solvent (d1). Heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

The time of the waiting step is, for example, 0.1 to 600 sec, and preferably 10 to 300 sec. If the waiting step is shorter than 0.1 sec, the bonding of the droplets of the curable composition (A) becomes insufficient, so no practically continuous liquid film is formed. If the waiting step exceeds 600 sec, the productivity decreases. To suppress the decrease in productivity, therefore, it is also possible to sequentially move substrates completely processed in the arranging step to the waiting step, perform the waiting step in parallel to a plurality of substrates, and sequentially move the substrates completely processed in the waiting step to the contact step. Note that in the related art, a few thousands of seconds to a few tens of thousands of seconds are theoretically required before a practically continuous liquid film is formed. In practice, however, no continuous liquid film can be formed because the spread of the droplets of the curable composition stagnates due to the influence of volatilization.

When the solvent (d1) volatilizes in the waiting step, the practically continuous liquid film 104 containing the components (a1), (b1), and (c1) remains. The average residual liquid film thickness of the practically continuous liquid film 104 from which the solvent (d1) volatilized (was removed) becomes smaller than the liquid film 103 by the volatilized amount of the solvent (d1). A state in which the entire pattern formation region of the substrate 101 is covered with the practically continuous liquid film 104 of the curable composition (A′) from which the solvent (d1) was removed is maintained in the entire region.

### <Contact Step>

In the contact step, as schematically shown in FIG. 1E, the mold 106 is brought into contact with the practically continuous liquid film 104 of the curable composition (A) from which the solvent (d1) is removed. The contact step includes a step of a changing a state in which the curable composition (A) and the mold 106 are not in contact with each other to a state in which they are in contact with each other, and a step of maintaining the state in which they are in contact with each other. As a consequence, the liquid of the curable composition (A) is filled in recesses of fine patterns on the surface of the mold 106, and the liquid forms a liquid film filled in the fine patterns of the mold 106.

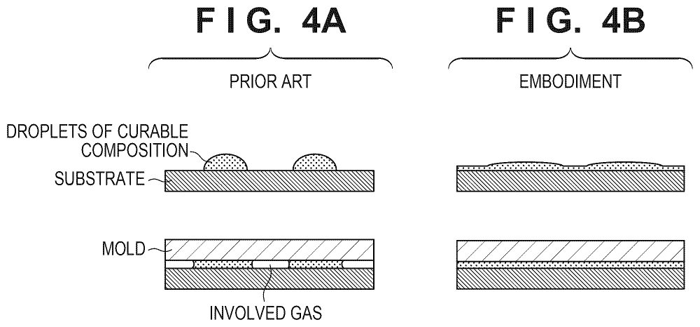

FIGS. 4A and 4B show comparison between a related art (for example, Japanese Patent No. 6584578) and this embodiment concerning a gas involved between the mold 106 and the substrate 101 in the contact step. According to this embodiment, the curable composition (A) forms the practically continuous liquid film 104 from which the solvent (d1) is removed in the waiting step, so the volume of a gas involved between the mold 106 and the substrate 101 becomes small, as compared to the related art. Accordingly, spreading of the curable composition (A) in the contact step is rapidly completed.

When spreading and filling of the curable composition (A) are quickly completed in the contact step, it is possible to shorten the time (the time required for the contact step) for maintaining the state in which the mold 106 is in contact with the curable composition (A). Since shortening the time required for the contact step leads to shortening the time required for pattern formation (film formation), the productivity improves. The contact step is preferably 0.1 sec or more and 3 sec or less, and particularly preferably 0.1 sec or more and 1 sec or less. If the contact step is shorter than 0.1 sec, spreading and filling become insufficient, so many defects called incomplete filling defects tend to occur.

When the curing step includes a light irradiation step, a mold made of a light-transmitting material is used as the mold 106 by taking this into consideration. Favorable practical examples of the type of the material forming the mold 106 are glass, quartz, PMMA, a photo-transparent resin such as a polycarbonate resin, a transparent metal deposition film, a soft film such as polydimethylsiloxane, a photo-cured film, and a metal film. When using the photo-transparent resin as the material forming the mold 106, a resin that does not dissolve in components contained in a curable composition is selected. Quartz is suitable as the material forming the mold 106 because the thermal expansion coefficient is small and pattern distortion is small.

A pattern formed on the surface of the mold 106 has a height of, for example, 4 nm or more and 200 nm or less. As the pattern height of the mold 106 decreases, it becomes possible to decrease the force of releasing the mold 106 from the cured film of the curable composition, that is, the mold release force in the mold release step, and this makes it possible to decrease the number of mold release defects remaining in the mold 106 because the pattern of the curable composition is torn off. Also, in some cases, the pattern of the curable composition elastically deforms due to the impact when the mold is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the substrate 101 decreases.

A surface treatment can also be performed on the mold 106 before performing the contact step, in order to improve the detachability of the mold 106 with respect to the curable composition (A). An example of this surface treatment is to form a mold release agent layer by coating the surface of the mold 106 with a mold release agent. Examples of the mold release agent to be applied on the surface of the mold 106 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the mold 106 into contact with the curable composition (A) is not particularly limited, and is, for example, 0 MPa or more and 100 MPa or less.

Note that when bringing the mold 106 into contact with the curable composition (A), the pressure to be applied to the curable composition (A) is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. A gas containing 10% or more of carbon dioxide or helium in a molar ratio is preferable, and a gas containing 10% or more of carbon dioxide in a molar ratio is particularly preferable. Since the helium gas readily diffuses into the mold, the substrate, the curable composition, and the like, the atmospheric gas confined in the mold pattern quickly disappears. Since carbon dioxide readily dissolves into the curable composition or the underlayer on the substrate, the atmospheric gas confined in the mold pattern quickly disappears. The solubility coefficient of carbon dioxide to the curable composition is preferably 0.5 kg/m³-atm or more and 10 kg/m³-atm or less. Details are disclosed in Japanese Patent Laid-Open No. 2022-99271. When performing the contact step in a specific gas atmosphere including a normal air atmosphere, a favorable pressure is 0.0001 atm or more and 10 atm or less.

### <Curing Step>

In the curing step, as schematically shown in FIG. 1F, the curable composition (A) is cured by being irradiated with irradiation light 107 as curing energy, thereby forming a cured film. In the curing step, for example, the curable composition (A) is irradiated with the irradiation light 107 through the mold 106. More specifically, the curable composition (A) filled in the fine pattern of the mold 106 is irradiated with the irradiation light 107 through the mold 106. Consequently, the curable composition (A) filled in the fine pattern of the mold 106 is cured and forms a cured film 108 having the pattern.

The irradiation light 107 is selected in accordance with the sensitivity wavelength of the curable composition (A). More specifically, the irradiation light 107 is properly selected from ultraviolet light, X-ray, and an electron beam each having a wavelength of 150 nm or more and 400 nm or less. Note that the irradiation light 107 is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources. Light can be emitted to the entire region of the curable composition (A) filled in the fine pattern of the mold, or to only a partial region thereof (by limiting the region). It is also possible to intermittently emit light to the entire region of the substrate a plurality of times, or to continuously emit light to the entire region of the substrate. Furthermore, a first region of the substrate can be irradiated with light in a first irradiation process, and a second region different from the first region of the substrate can be irradiated with light in a second irradiation process.

### <Mold Release Step>

In the mold release step, as schematically shown in FIG. 1G, the mold 106 is released from the cured film 108. When the mold 106 is released from the cured film 108 having the pattern, the cured film 108 having a pattern formed by inverting the fine pattern of the mold 106 is obtained in an independent state. In this state, a cured film remains in recesses of the cured film 108 having the pattern. This film is called a residual film.

A method of releasing the mold 106 from the cured film 108 having the pattern can be any method provided that the method does not physically break a part of the cured film 108 having the pattern during the release, and various conditions and the like are not particularly limited. For example, it is possible to fix the substrate 101 and move the mold 106 away from the substrate 101. It is also possible to fix the mold 106 and move the substrate 101 away from the mold 106. Furthermore, the mold 106 can be released from the cured film 108 having the pattern by moving both the mold 106 and the substrate 101 in exactly opposite directions.

### <Repetition>

A series of steps (a fabrication process) having the above-described steps from the arranging step to the mold release step in this order make it possible to obtain a cured film having a desired uneven pattern shape (a pattern shape conforming to the uneven shape of the mold 106) in a desired position.

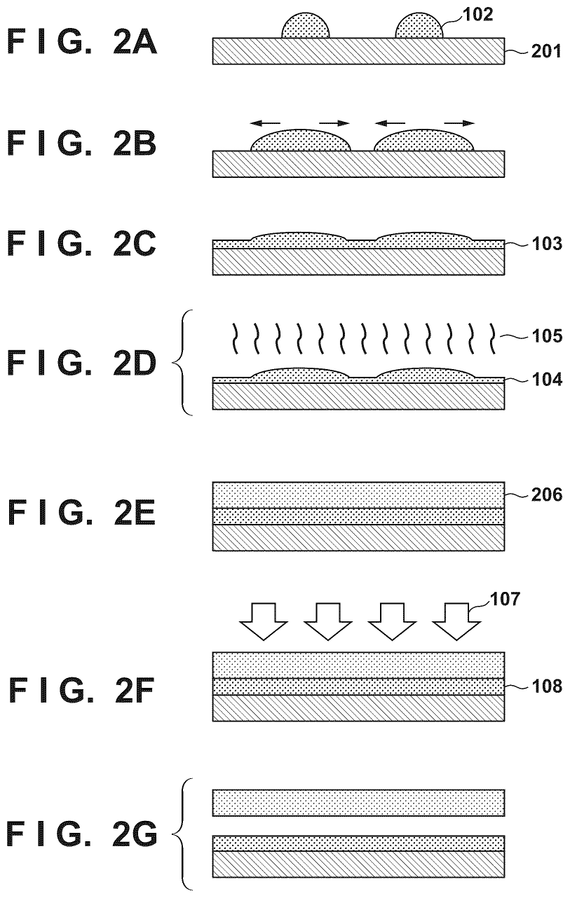

In the pattern forming method of the present disclosure, a repetition unit (shot) from the arranging step to the mold release step can repetitively be performed a plurality of times on the same substrate, so the cured film 108 having a plurality of desired patterns in desired positions of the substrate can be obtained.

[Reverse Imprint Pattern Forming Method]A pattern forming method according to another example will be explained with reference to FIGS. 2A to 2G. The cured film formed by the present disclosure is preferably a film having a pattern with a size of 1 nm or more and 10 mm or less, and more preferably a film having a pattern with a size of 10 nm or more and 100 μm or less. Generally, a film forming method of forming a film having a pattern (uneven structure) of a nano size (1 nm or more and 100 nm or less) by using light is called a photoimprint method. The film forming method of the present disclosure forms a film of a curable composition in a space between a mold and a substrate by using the photoimprint method. However, the curable composition can also be cured by other energy (for example, heat or an electromagnetic wave). A film forming method of the present disclosure can be performed as a method of forming a film having a pattern, that is, as a pattern forming method, and can also be performed as a method of forming a film (for example, a planarization film) having no pattern, that is, as a planarization film forming method.

An example in which the film forming method of the present disclosure is applied to the pattern forming method will be explained below. The pattern forming method includes, for example, a forming step, an arranging step, a waiting step, a contact step, a curing step, and a mold release step. The forming step is a step of forming an underlayer. The arranging step is a step of discretely arranging droplets of the curable composition (A) on the underlayer. The waiting step is a step of waiting until the droplets of the curable composition (A) bond to each other and the solvent (d1) volatilizes. The contact step is a step of bringing the curable composition (A) and a mold in contact with each other. The curing step is a step of curing the curable composition (A). The mold release step is a step of releasing the mold from the cured film of the curable composition (A). The arranging step is performed after the forming step, the waiting step is performed after the arranging step, the contact step is performed after the waiting step, the curing step is performed after the contact step, and the mold release step is performed after the curing step.

### <Arranging Step>

FIGS. 2A to 2G are different from FIGS. 1A to 1G in that the positional relationship between the mold and the substrate is reversed. Hence, the method shown in FIGS. 2A to 2G can be called “reverse imprint”. In an example, the mold can be a blank template that is the base of a replica mold. In the arranging step, as schematically shown in FIG. 2A, the droplets 102 of the curable composition (A) are discretely arranged on a mold 201. In the arranging step, the droplets 102 of the curable composition (A) having a volume of 1.0 pL or more are arranged at a density of 80 droplets/mm² or more.

When the curing step includes a light irradiation step, a mold made of a light-transmitting material is used as the mold 201 by taking this into consideration. Favorable practical examples of the type of the material forming the mold 201 are glass, quartz, PMMA, a photo-transparent resin such as a polycarbonate resin, a transparent metal deposition film, a soft film such as polydimethylsiloxane, a photo-cured film, and a metal film. When using the photo-transparent resin as the material forming the mold 201, a resin that does not dissolve in components contained in a curable composition is selected. Quartz is suitable as the material forming the mold 201 because the thermal expansion coefficient is small and pattern distortion is small.

An inkjet method is particularly favorable as the arranging method of arranging the droplets 102 of the curable composition (A) on the mold. It is favorable to arrange the droplets 102 of the curable composition (A) densely on that region of the mold 201, which faces a region in which recesses forming the pattern of the substrate 206 densely exist, and sparsely on that region of the mold 201, which faces a region in which recesses forming the pattern of the substrate 206 sparsely exist. Consequently, the film (residual film) (to be described later) of the curable composition (A) formed on the mold 201 is controlled to have a uniform thickness regardless of the sparsity and density of the pattern of the substrate 206.

An index called an average residual liquid film thickness is defined in order to prescribe the volume of the curable composition (A′) to be arranged. The average residual liquid film thickness is a value obtained by dividing the volume of the curable composition (A′) to be arranged in the arranging step by the area of a film formation region of the mold. The volume of the curable composition (A′) (except the solvent (d1)) is the sum total of the volumes of the individual droplets of the curable composition (A) after the solvent (d1) volatilized. According to this definition, the average residual liquid film thickness can be prescribed regardless of the state of unevenness even when the substrate surface is uneven. Here, the average residual liquid film thickness may be understood as a value obtained by dividing the volume of the curable composition (A′) remaining after the waiting step to be described later by the area of the film formation region of the mold, and is preferably 20 nm or less.

### <Waiting Step>

In the present disclosure, the waiting step is provided during time after the arranging step and before the contact step. Here, a value obtained by dividing the total volume of the droplets of the curable composition (A) dropped in one-time pattern formation by the total area of regions (pattern formation regions) in which patterns are formed in one-time pattern formation is defined as an average initial liquid film thickness. In the waiting step, as schematically shown in FIG. 2B, the droplets 102 of the curable composition (A) spread on the mold 201. Consequently, the whole pattern formation region of the mold 201 is covered with the curable composition (A).

According to an example to be described later, for example, a case where the solvent (d1) is a highly volatile solvent, the volume ratio of nonvolatile components is 20%, and the droplet pitch is 88 μm, that is, the average initial liquid film thickness is 13 nm or more is selected. In this case, as schematically shown in FIG. 2C, it is indicated by numerical calculation that the droplets of the curable composition (A′) bond to each other on the substrate, and a practically continuous liquid film 103 is formed. Also, this means that the droplets of the curable composition (A) having a volume of 1.0 pL or more are arranged at a density of 130 droplets/mm².

The flow behavior during the waiting step of the droplets of the curable composition (A) arranged on the substrate, which has been described with reference to FIGS. 3A to 3D, is the same as that described with reference to FIGS. 3A to 3D.

In addition, as schematically shown in FIG. 2D, the solvent 105 (solvent (d1)) contained in a liquid film 104 is volatilized in the waiting step. Assuming that the total weight of the components except for the solvent (d1) is 100 vol %, the residual amount of the solvent (d1) in the liquid film 103 after the waiting step (for example, at the start of the contact step) is preferably 10 vol % or less. If the residual amount of the solvent (d1) is larger than 10 vol %, the mechanical properties of the cured film may deteriorate.

In the waiting step, it is possible to perform a baking step of heating the mold 201 and the curable composition (A), or ventilate the atmospheric gas around the mold 201, for the purpose of accelerating the volatilization of the solvent (d1). Heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

The time of the waiting step is, for example, 0.1 to 600 sec, and preferably 10 to 300 sec. If the waiting step is shorter than 0.1 sec, the bonding of the droplets of the curable composition (A) becomes insufficient, so no practically continuous liquid film is formed. If the waiting step exceeds 600 sec, the productivity decreases. To suppress the decrease in productivity, therefore, it is also possible to sequentially move substrates completely processed in the arranging step to the waiting step, perform the waiting step in parallel to a plurality of substrates, and sequentially move the substrates completely processed in the waiting step to the contact step. Note that in the related art, a few thousands of seconds to a few tens of thousands of seconds are theoretically required before a practically continuous liquid film is formed. In practice, however, no continuous liquid film can be formed because the spread of the droplets of the curable composition stagnates due to the influence of volatilization.

When the solvent (d1) volatilizes in the waiting step, the practically continuous liquid film 104 containing the components (a1), (b1), and (c1) remains. The average residual liquid film thickness of the practically continuous liquid film 104 from which the solvent (d1) volatilized (was removed) becomes smaller than the liquid film 103 by the volatilized amount of the solvent (d1). A state in which the entire pattern formation region of the substrate 101 is covered with the practically continuous liquid film 104 of the curable composition (A′) from which the solvent (d1) was removed is maintained in the entire region.

### <Contact Step>

In the contact step, as schematically shown in FIG. 2E, the substrate 206 is brought into contact with the practically continuous liquid film 104 of the curable composition (A) from which the solvent (d1) is removed. The contact step includes a step of a changing a state in which the curable composition (A) and the substrate 206 are not in contact with each other to a state in which they are in contact with each other, and a step of maintaining the state in which they are in contact with each other. As a consequence, the liquid of the curable composition (A) is filled in recesses of fine patterns on the surface of the substrate 206, and the liquid forms a liquid film filled in the fine patterns of the substrate 206.

FIGS. 4A and 4B show comparison between a related art (for example, Japanese Patent No. 6584578) and this embodiment concerning a gas involved between the mold 106 and the substrate 101 in the contact step. According to this embodiment (FIG. 4B), the curable composition (A) forms the practically continuous liquid film 104 from which the solvent (d1) is removed in the waiting step, so the volume of a gas involved between the mold 106 and the substrate 101 becomes small, as compared to the related art (FIG. 4A). Accordingly, spreading of the curable composition (A) in the contact step is rapidly completed.

When spreading and filling of the curable composition (A) are quickly completed in the contact step, it is possible to shorten the time (the time required for the contact step) for maintaining the state in which the substrate 206 is in contact with the curable composition (A). Since shortening the time required for the contact step leads to shortening the time required for pattern formation (film formation), the productivity improves. The contact step is preferably 0.1 sec or more and 3 sec or less, and particularly preferably 0.1 sec or more and 1 sec or less. If the contact step is shorter than 0.1 sec, spreading and filling become insufficient, so many defects called incomplete filling defects tend to occur.

As the substrate 206, a substrate on which an underlayer is stacked may be used. In addition, the above-described layer forming composition is preferably formed on the surface of the substrate 206, and the adhesion with respect to the curable composition (A) can be improved by a surface treatment such as a silane coupling treatment, a silazane treatment, or deposition of an organic thin film.

As the silane coupling agent, a known silane coupling agent having an acrylic group can be used. As a method of applying the silane coupling agent, for example, an inkjet method, a dip coating method, an air knife coating method, a curtain coating method, a wire bar coating method, a gravure coating method, an extrusion coating method, a spin coating method, a slit scanning method, or a vapor deposition method can be used. The vapor deposition method is particularly favorable among these methods from the viewpoint of applicability, particularly, film thickness evenness.

Also, as the substrate 206, a silicon substrate that has not undergone a surface treatment can also be used.

A pattern formed on the surface of the substrate 206 has a height of, for example, 4 nm or more and 200 nm or less. As the pattern height of the substrate 206 decreases, it becomes possible to decrease the force of releasing the substrate 206 from the cured film of the curable composition, that is, the mold release force in the mold release step, and this makes it possible to decrease the number of mold release defects remaining in the substrate 206 because the pattern of the curable composition is torn off. Also, in some cases, the pattern of the curable composition elastically deforms due to the impact when the mold is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the mold 201 decreases.

A surface treatment can also be performed on the substrate 206 before performing the contact step, in order to improve the detachability of the substrate 206 with respect to the curable composition (A). An example of this surface treatment is to form a mold release agent layer by coating the surface of the substrate 206 with a mold release agent. Examples of the mold release agent to be applied on the surface of the substrate 206 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the substrate 206 into contact with the curable composition (A) is not particularly limited, and is, for example, 0 MPa or more and 100 MPa or less. Note that when bringing the substrate 206 into contact with the curable composition (A), the pressure to be applied to the curable composition (A) is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction.

Practical examples of an inert gas to be used when performing the contact step in the inert-gas atmosphere are nitrogen, carbon dioxide, helium, argon, various freon gases, and gas mixtures thereof. A gas containing 10% or more of carbon dioxide or helium in a molar ratio is preferable, and a gas containing 10% or more of carbon dioxide in a molar ratio is particularly preferable. Since the helium gas readily diffuses into the mold, the substrate, the curable composition, and the like, the atmospheric gas confined in the mold pattern quickly disappears. Since carbon dioxide readily dissolves to the curable composition or the underlayer on the substrate, the atmospheric gas confined in the mold pattern quickly disappears. The solubility coefficient of carbon dioxide to the curable composition is preferably 0.5 kg/m³.atm or more and 10 kg/m³.atm or less. Details are disclosed in Japanese Patent Laid-Open No. 2022-99271. When performing the contact step in a specific gas atmosphere including a normal air atmosphere, a favorable pressure is 0.0001 atm or more and 10 atm or less.

### <Curing Step>

In the curing step, as schematically shown in FIG. 2F, the curable composition (A) is cured by being irradiated with irradiation light 107 as curing energy, thereby forming a cured film. In the curing step, for example, the curable composition (A) is irradiated with the irradiation light 107 through the substrate 206. More specifically, the curable composition (A) filled in the fine pattern of the substrate 206 is irradiated with the irradiation light 107 through the substrate 206. Consequently, the curable composition (A) filled in the fine pattern of the substrate 206 is cured and forms the cured film 108 having the pattern.

The irradiation light 107 is selected in accordance with the sensitivity wavelength of the curable composition (A). More specifically, the irradiation light 107 is properly selected from ultraviolet light, X-ray, and an electron beam each having a wavelength of 150 nm or more and 400 nm or less. Note that the irradiation light 107 is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources. Light can be emitted to the entire region of the curable composition (A) filled in the fine pattern of the mold, or to only a partial region thereof (by limiting the region). It is also possible to intermittently emit light to the entire region of the substrate a plurality of times, or to continuously emit light to the entire region of the substrate. Furthermore, a first region of the substrate can be irradiated with light in a first irradiation process, and a second region different from the first region of the substrate can be irradiated with light in a second irradiation process.

### <Mold Release Step>

In the mold release step, as schematically shown in FIG. 2G, the substrate 206 is released from the cured film 108. When the substrate 206 is released from the cured film 108 having the pattern, the cured film 108 having a pattern formed by inverting the fine pattern of the substrate 206 is obtained in an independent state. In this state, a cured film remains in recesses of the cured film 108 having the pattern. This film is called a residual film.

A method of releasing the substrate 206 from the cured film 108 having the pattern can be any method provided that the method does not physically break a part of the cured film 108 having the pattern during the release, and various conditions and the like are not particularly limited. For example, it is possible to fix the mold 201 and move the substrate 206 away from the mold 201. It is also possible to fix the substrate 206 and move the mold 201 away from the substrate 206. Furthermore, the substrate 206 can be released from the cured film 108 having the pattern by moving both the substrate 206 and the mold 201 in exactly opposite directions.

### <Repetition>

A series of steps (a fabrication process) having the above-described steps from the arranging step to the mold release step in this order make it possible to obtain a cured film having a desired uneven pattern shape (a pattern shape conforming to the uneven shape of the substrate 206) in a desired position.

In the pattern forming method of the present disclosure, a repetition unit (shot) from the arranging step to the mold release step can repetitively be performed a plurality of times on the same mold, so the cured film 108 having a plurality of desired patterns in desired positions of the mold can be obtained.

### [Planarization Film Forming Method]

An example in which the film forming method of the present disclosure is applied to a planarization film forming method will be explained below. The planarization film forming method includes, for example, an arranging step, a waiting step, a contact step, a curing step, and a mold release step. The arranging step is a step of arranging droplets of the curable composition (A) on a substrate. The waiting step is a step of waiting until the droplets of the curable composition (A) bond to each other and the solvent (d1) volatilizes. The contact step is a step of bringing the curable composition (A) and a mold into contact with each other. The curing step is a step of curing the curable composition (A). The mold release step is a step of releasing the mold from the cured film of the curable composition (A). In the planarization film forming method, a substrate having unevenness having a difference in height of about 10 to 1,000 nm is used as the substrate, a mold having a flat surface is used as the mold, and a cured film having a surface conforming to the flat surface of the mold is formed through the contact step, the curing step, and the mold release step. In the arranging step, the droplets of the curable composition (A) are densely arranged in recesses of the substrate, and sparsely arranged on projections of the substrate. The waiting step is performed after the arranging step, the contact step is performed after the waiting step, the curing step is performed after the contact step, and the mold release step is performed after the curing step.

In the planarization film forming method, a mold including a flat surface is used, as described above. Such a mold can also be called a superstrate. In this mold, the whole surface of the contact region to the curable composition can be a flat surface without a pattern. However, an alignment mark or pattern is sometimes formed in a part of the contact region to the curable composition. Hence, for example, not less than 90% the contact region to the curable composition can have a flat surface.

### [Article Manufacturing Method]

An article manufacturing method includes a forming step of forming a film of a curable composition on a substrate using the above-described film forming method, a processing step of processing the substrate on which the film of the curable composition is formed in the forming step, and a manufacturing step of manufacturing an article from the substrate processed in the processing step. The film forming method is a pattern forming method or a planarization film forming method, as described above.

The cured film 108 having a pattern formed by the pattern forming method of the present disclosure can directly be used as at least a partial constituent member of various kinds of articles. Also, the cured film 108 having a pattern formed by the pattern forming method of the present disclosure can temporarily be used as a mask for etching or ion implantation with respect to the substrate 101 (a layer to be processed when the substrate 101 has the layer to be processed). This mask is removed after etching or ion implantation is performed in a processing step of the substrate 101. Consequently, various kinds of articles can be manufactured.

When removing a cured product in recesses of a pattern of the cured product by etching, a practical method is not particularly limited, and a conventionally known method such as dry etching can be used. A conventionally known dry etching apparatus can be used in this dry etching. A source gas for dry etching is appropriately selected in accordance with an element composition of the cured product to be etched. More specifically, it is possible to use halogen gases such as CF₄, C₂F₆, C₃F₈, CCl₂F₂, CCl₄, CBrF₃, BCl₃, PCl₃, SF₆, and Cl₂ as the source gas. As the source gas, it is also possible to use gases containing oxygen atoms such as O₂, CO, and CO₂, inert gases such as He, N₂, and Ar, and gases such as H₂ and NH₃ as the source gas. Note that these gases can also be mixed and used as the source gas. In this case, the photo-cured film is required to have a high dry etching resistance in order to process the base substrate with high yield.

An article is, for example, an electric circuit element, an optical element, MEMS, a recording element, a sensor, or a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. Examples of the optical element are a micro lens, a light guide body, a waveguide, an antireflection film, a diffraction grating, a polarizer, a color filter, a light-emitting element, a display, and a solar battery. Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprinting.

In addition, a well-known photolithography step such as an imprint lithography technique or an extreme ultraviolet exposure technique (EUV) can be performed on the planarization film formed by the planarization film forming method of the present disclosure. It is also possible to stack a spin-on-glass (SOG) film and/or a silicon oxide layer, and perform a photolithography step by applying a curable composition on that. Consequently, a device such as a semiconductor device can be fabricated. It is further possible to form an apparatus including the device, for example, an electronic apparatus such as a display, a camera, or a medical apparatus. Examples of the device are an LSI, a system LSI, a DRAM, an SDRAM, an RDRAM, a D-RDRAM, and a NAND flash memory.

### Examples

Examples will be described below in detail, but the technical scope of the present invention is not limited to the following examples. Note that “parts” and “%” used below are on a weight basis unless otherwise specified.

### [Preparation of Curable Composition]

A polymerizable compound (a1), a photopolymerization initiator (b1), a solvent (d1), and a surfactant (c1) shown below were mixed in weights (%) shown in Table 1, and the resultant mixture was filtered using a polyethylene filter having a pore diameter of 0.005 μm. Curable compositions 1 to 6 were thus prepared.

TABLE 1

| | | | | | | boiling | viscosity |
|---|---|---|---|---|---|---|---|
| | | | | | amount of | point | of the |
| | | | | | solvent | of the | curable |
| | Polymerizable | Photopolymerization | Solvent | Surfactant | to whole | solvent | composition |
| | compound (a1) | initiator (b1) | (d1) | (c1) | [volume] | [° C.] | [mPa · s] |
| Curable | DCPDA | Omnirad819 | PGMEA | — | 40 | 146 | 8.45 |
| composition 1 | (100 parts | (3 parts | | | | | |
| | by weight) | by weight) | | | | | |
| Curable | DCPDA | Omnirad819 | PGMEA | FS2000M1 | 40 | 146 | 8.50 |
| composition 2 | (100 parts | (3 parts | | (0.4 parts | | | |
| | by weight) | by weight) | | by weight) | | | |
| Curable | DCPDA | Omnirad819 | PGMEA | — | 60 | 146 | 3.20 |
| composition 3 | (100 parts | (3 parts | | | | | |
| | by weight) | by weight) | | | | | |
| Curable | DCPDA | Omnirad819 | PGMEA | FS2000M1 | 60 | 146 | 3.28 |
| composition 4 | (100 parts | (3 parts | | (0.4 parts | | | |
| | by weight) | by weight) | | by weight) | | | |
| Curable | DCPDA | Omnirad819 | PGMEA | — | 80 | 146 | 1.95 |
| composition 5 | (100 parts | (3 parts | | | | | |
| | by weight) | by weight) | | | | | |
| Curable | DCPDA | Omnirad819 | PGMEA | FS2000M1 | 80 | 146 | 1.96 |
| composition 6 | (100 parts | (3 parts | | (0.4 parts | | | |
| | by weight) | by weight) | | by weight) | | | |

Abbreviations in Table 1 are as follows.
DCPA: dimethylol-tricyclodecanediacrylate (manufactured by KYOEISHA CHEMICAL)
Omnirad 819: phenylbis(2,4,6-trimethylbenzoyl)phosphine oxide (manufactured by IGM Resin)
PGMEA: propylene glycol monomethyl ether acetate (manufactured by KANTO CHEMICAL)
FS2000M1: fluorosurfactants (manufactured by CHANGZHOU FOREIGN)

### [Preparation of Layer Forming Composition 1]

A compound (a2-1) and a cross-linker (b2) were dissolved in a volatile solvent (d2-1) in weights (%) shown below.
compound (a2-1) 0.2775
cross-linker (b2-1) 0.0692
volatile solvent (d2-1) 99.6533

The obtained solution mixture was filtered using a polyethylene filter having a pore diameter of 0.005 μm. Layer forming composition 1 was thus prepared.

Abbreviations in Table 1 are as follows.

(Compound (a2-1))

Carboxylic anhydride-modified cresol novolac epoxy acrylate (manufactured by SHIN-NAKAMURA CHEMICAL, product name: EA-7140) (formula (1))

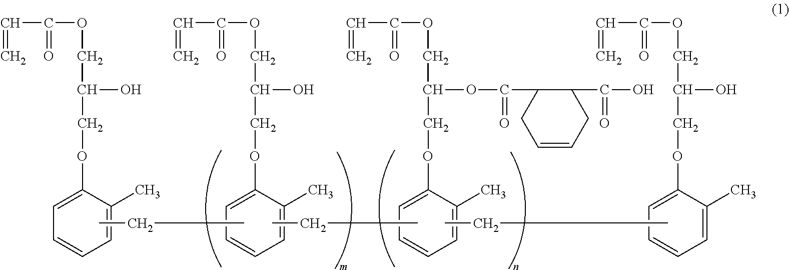

(Cross-Linker (b2-1))

2,4,6-tris[bis(methoxymethyl)amino]-1,3,5-triazine (manufactured by Tokyo Chemical Industry) (formula (2))

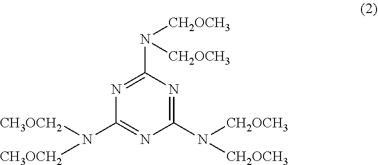

(Volatile Solvent (d2-1))

propylene glycol monomethyl ether acetate (manufactured by Tokyo Chemical Industry)

### [Layer Forming Composition 2]

For layer forming composition 2, a layer forming composition FULS-013D manufactured by Fuji Film was used.

### [Formation of Adhesion Layers 1 and 2]

Layer forming compositions 1 and 2 described above were each applied to a silicon wafer having a size of 2 inches by spin coating. After that, baking was performed under conditions of 220° C. for 90 sec, thereby forming adhesion layers 1 and 2.

### [Contact Angle of Curable Composition to Adhesion Layer]

To measure the contact angle of a curable composition to an adhesion layer, an industrial material printer DMP-2850 (manufactured by Fuji Film) was used. The droplet volume was set to 1 to 2 pL, and droplets immediately after these adhere to an adhesion layer were captured by the surface camera of the apparatus. From a droplet diameter measured by image analysis, the contact angle was calculated using equations (4) and (5).

If it is assumed that a droplet spreads while maintaining its spherical shape, the relationship between a droplet radius r and a height h can be expressed as follows. Abbreviations in equations below are as follows.
r: droplet radius
V: droplet volume
h: droplet height
r0: radius when the initial shape is semispherical

$${r}^{2} = \frac{2 V}{π h} - \frac{1}{3} {h}^{2} , R = \frac{{r}^{2} + {h}^{2}}{2 h} , {r = R sin θ}_{R : radius of sphere} , h = R - R cos θ , d = 2 r \qquad ( 4 )$$

$$V = \frac{1}{2} \frac{4}{3} π {r}_{0}^{3} ⇔ {r}_{0} = \sqrt[3]{\frac{3 V}{2 π}} \frac{π h}{6} ( 3 {r}^{2} + {h}^{3} ) = V \qquad ( 5 )$$

[Contact Angle of Composition Obtained by Removing Solvent from Curable Composition to Adhesion Layer]

To measure the contact angle, the amount of droplets was set to 1 μL, and an automatic static contact angle meter Dropmaster 300 (manufactured by Kyowa Interface Science) was used. An equilibrium contact angle after the solvent completely volatilized (for example, the contact angle 15 sec after droplet adhesion) was measured.

### Example 1

In Example 1, measurement results of the droplet diameter, the contact angle of curable composition 1 to adhesion layer 1, and the contact angle of a composition obtained by removing the solvent from the curable composition to adhesion layer 1, which are measured above, are shown.

### Examples 2 to 24

The curable composition and the adhesion layer used in Example 1 were changed as shown in Table 2, and Examples 2 to 24 were executed.

TABLE 2

| | | | | | Contact angle of Curable composition to | |
|---|---|---|---|---|---|---|
| | | | Nonvolatile | Viscosity | adhesion layer (or silicon substrate) [°] | |
| | | | component | of curable | before | after |
| | Curable | Adhesion | concentration | composition | removal | removal |
| | composition | layer | [vol %] | [mPa · s] | of solvent | of solvent |
| Example 1 | curable | adhesion | 60 | 8.45 | 0.2 | 17 |
| | composition 1 | layer 1 | | | | |
| Example 2 | curable | adhesion | 60 | 8.45 | 0.6 | 19 |
| | composition 1 | layer 1 | | | | |
| Example 3 | curable | adhesion | 60 | 8.45 | 1.8 | 18 |
| | composition 1 | layer 1 | | | | |
| Example 4 | curable | adhesion | 40 | 3.20 | 0.4 | 15 |
| | composition 3 | layer 1 | | | | |
| Example 5 | curable | adhesion | 40 | 3.20 | 1.1 | 13 |
| | composition 3 | layer 1 | | | | |
| Example 6 | curable | adhesion | 20 | 1.95 | 1.1 | 11 |
| | composition 5 | layer 1 | | | | |
| Example 7 | curable | — | 60 | 8.45 | 0.2 | 18 |
| | composition 1 | | | | | |
| Example 8 | curable | — | 60 | 8.45 | 0.6 | 19 |
| | composition 1 | | | | | |
| Example 9 | curable | adhesion | 60 | 8.45 | 1.8 | 12 |
| | composition 1 | layer 2 | | | | |
| Example | curable | — | 40 | 3.20 | 0.4 | 13 |
| 10 | composition 3 | | | | | |
| Example | curable | — | 40 | 3.20 | 1.1 | 14 |
| 11 | composition 3 | | | | | |
| Example | curable | — | 20 | 1.95 | 1.1 | 11 |
| 12 | composition 5 | | | | | |
| Example | curable | adhesion | 60 | 8.50 | 0.2 | 17 |
| 13 | composition 2 | layer 1 | | | | |
| Example | curable | adhesion | 60 | 8.50 | 0.6 | 19 |
| 14 | composition 2 | layer 1 | | | | |
| Example | curable | adhesion | | 8.50 | 1.8 | 18 |
| 15 | composition 2 | layer 1 | 60 | | | |
| Example | curable | adhesion | 40 | 3.28 | 0.4 | 15 |
| 16 | composition 4 | layer 1 | | | | |
| Example | curable | adhesion | 40 | 3.28 | 1.1 | 13 |
| 17 | composition 4 | layer 1 | | | | |
| Example | curable | adhesion | 20 | 1.96 | 1.1 | 11 |
| 18 | composition 6 | layer 1 | | | | |
| Example | curable | — | 60 | 8.50 | 0.2 | 16 |
| 19 | composition 2 | | | | | |
| Example | curable | — | 60 | 8.50 | 0.6 | 15 |
| 20 | composition 2 | | | | | |
| Example | curable | adhesion | 60 | 8.50 | 1.8 | 13 |
| 21 | composition 2 | layer 2 | | | | |
| Example | curable | — | 40 | 3.28 | 0.4 | 12 |
| 22 | composition 4 | | | | | |
| Example | curable | — | 40 | 3.28 | 1.1 | 14 |
| 23 | composition 4 | | | | | |
| Example | curable | — | 20 | 1.96 | 1.1 | 11 |
| 24 | composition 6 | | | | | |
| Comparative | curable | — | 60 | 8.45 | 23 | 10 |
| example 1 | composition 1 | | | | | |
| Comparative | curable | adhesion | 60 | 8.50 | 0.1 | 9 |
| example 2 | composition 2 | layer 1 | | | | |
| Comparative | curable | adhesion | | | | |
| example 3 | composition 2 | layer 2 | 60 | 8.50 | 3 | 20 |

### <Evaluation of Discharge of Inkjet>

To evaluate discharge of inkjet, a commercially available industrial material printer DMP-2850 (manufactured by Fuji Film) was used. Each of the curable compositions of Examples 1 to 24 and Comparative Examples 1 to 3 shown in Table 2 was filled in a cartridge. A droplet discharge state was observed by an internal discharge observation camera, and the discharge of inkjet was evaluated based on the following evaluation criteria.

### (Evaluation Criteria)

AAA: no deviation of landing positions was observed at all at a discharge speed (flying speed) of 5 m/sec or more.
AA: a slight deviation of landing positions without any practical influence was observed at a discharge speed of 5 m/sec or more.
A: a slight deviation of landing positions without any practical influence was observed at a discharge speed of 3 m/sec or more.
B: no discharge was performed.

### <Evaluation of Liquid Film Formation>

To evaluate liquid film formation, a commercially available industrial material printer DMP-2850 (manufactured by Fuji Film) was used. Each of the curable compositions of Examples 1 to 24 and Comparative Examples 1 to 3 shown in Table 2 was filled in a cartridge. Under such conditions that a film thickness of 160 nm or less was obtained after volatilization of the solvent (d1), droplets of about 2 pl were dropped (arranged) on an adhesion layer or a silicon substrate in an array of 6 rows at four types of pitch interval's (35, 50, 70, and 122 μm). Liquid film formation was evaluated based on the following evaluation criteria.

### (Evaluation Criteria)

AAA: a practically continuous liquid film was formed at any pitch interval.
AA: a practically continuous liquid film was formed at pitch intervals of 35, 50, and 70 μm.
A: a practically continuous liquid film was formed at pitch intervals of 35 and 50 μm.
B: a practically continuous liquid film was formed at a pitch interval of 35 μm.
C: no practically continuous liquid film was formed at any pitch interval.

### <Evaluation of Liquid Film Stability>

To evaluate liquid film stability, a commercially available industrial material printer DMP-2850 (manufactured by Fuji Film) was used. In the above-described evaluation of liquid film formation, after the liquid film was formed, time in which the liquid film could be maintained without shrinkage was measured, and liquid film stability was evaluated based on the following evaluation criteria. Note that “shrinkage” is defined as a state in which the length of the liquid film is less than a designed liquid film region.

### (Evaluation Criteria)

AAA: no shrinkage occurred for 600 sec or more.
AA: no shrinkage occurred for 300 sec or more and less than 600 sec.
A: no shrinkage occurred for 180 sec or more and less than 300 sec.
B: shrinkage occurred within 180 sec.

### <Evaluation of Extrusion Amount>

To evaluate the extrusion amount, a commercially available industrial material printer DMP-2850 (manufactured by Fuji Film) was used. In the above-described evaluation of liquid film formation, after the liquid film was formed, it was confirmed that the liquid film after the elapse of 180 sec formed a practically continuous liquid film, and the extrusion amount was measured. Note that the extrusion amount of the liquid film is defined as an amount obtained by subtracting 70×6 μm (designed liquid film region) from the length of the liquid film, and the extrusion amount was evaluated based on the following evaluation criteria.

### (Evaluation Criteria)

AAA: the extrusion amount was 50 μm or less.
AA: the extrusion amount was 70 μm or less.
A: the extrusion amount was 100 μm or less.
B: the extrusion amount was larger than 100 μm.
The evaluation results are shown in Table 3.

TABLE 3

| | Evaluation result | | | |
|---|---|---|---|---|
| | IJ | liquid film | liquid film | extrusion |
| | discharge | formation | stability | amount |
| Example 1 | AAA | AAA | A | AAA |
| Example 2 | AAA | AAA | A | AAA |
| Example 3 | AAA | A | A | AAA |
| Example 4 | AA | AAA | AA | AA |
| Example 5 | A | AA | AA | AA |
| Example 6 | B | AA | AAA | A |
| Example 7 | AAA | AAA | A | AAA |
| Example 8 | AAA | AAA | A | AAA |
| Example 9 | AAA | A | AA | A |
| Example 10 | AA | AAA | AA | A |
| Example 11 | AA | AA | AA | AA |
| Example 12 | B | AA | AAA | A |
| Example 13 | AAA | AAA | A | AAA |
| Example 14 | AAA | AAA | A | AAA |
| Example 15 | AAA | A | A | AAA |
| Example 16 | AA | AAA | AA | AA |
| Example 17 | AA | AA | AA | AA |
| Example 18 | A | AA | AAA | A |
| Example 19 | AAA | AAA | A | AA |
| Example 20 | AAA | AAA | A | AA |
| Example 21 | AAA | B | AA | AA |
| Example 22 | AA | AAA | AA | A |
| Example 23 | AA | AA | AA | AA |
| Example 24 | A | AA | AAA | A |
| Comparative | AAA | C | — | — |
| example 1 | | | | |
| Comparative | AAA | AA | AAA | B |
| example 2 | | | | |
| Comparative | AAA | AA | B | — |
| example 3 | | | | |

It is found that if the viscosity of the curable composition at 23° C. is 1.9 mPa·s or less, inkjet (IJ) discharge is excellent, and the viscosity is preferably 3 mPa·s or more and 60 mPa·s or less, and more preferably 8 mPa·s or more and 60 mPa·s or less.

It is found that if the contact angle of the curable composition to the adhesion layer or the silicon substrate is 1.8[°] or less, liquid film formation is excellent, and the contact angle is preferably 1.1[°] or less, and more preferably 0.6[°] or less.

It is found that if the contact angle of the composition obtained by removing the solvent from the curable composition to the adhesion layer or the silicon substrate is 19[°] or less, liquid film stability is excellent, and the contact angle is preferably 15[°] or less, and more preferably 11[°] or less.

It is found that if the contact angle of the composition obtained by removing the solvent from the curable composition to the adhesion layer or the silicon substrate is 11[°] or more, the extrusion amount is excellent, and the contact angle is preferably 13[°] or more, and more preferably 17[°] or more.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-040189, filed Mar. 14, 2024, which is hereby incorporated by reference herein in its entirety.

What is claimed is:

1. A material kit including a curable composition, and a layer forming composition configured to form an adhesion layer that adheres a substrate and the curable composition, wherein
the curable composition contains a polymerizable compound (a1), a photopolymerization initiator (b1), and a solvent (d1),
a viscosity of the curable composition at 23° C. and at 1 atm is not less than 1.3 mPa·s and not more than 60 mPa·s,
a content of the solvent (d1) with respect to a total volume of the polymerizable compound (a1), the photopolymerization initiator (b1), and the solvent (d1) is not less than 5 vol % and not more than 95 vol %,
a boiling point of the solvent (d1) is less than 250° C. at 1 atm,
a contact angle of the curable composition to the adhesion layer is not more than 1.8[°], and
the contact angle of a composition in a state in which the solvent (d1) is removed from the curable composition to the adhesion layer is not less than 11[° ] and not more than 19[°].

2. The kit according to claim 1, wherein the contact angle of the curable composition to the adhesion layer is not more than 1.0[°].

3. The kit according to claim 1, wherein the composition in the state in which the solvent (d1) is removed from the curable composition has a viscosity of not less than 30 mPa·s and not more than 10,000 mPa·s at 23° C. and at 1 atm.

4. The kit according to claim 1, wherein the curable composition is a curable composition for inkjet.

5. The kit according to claim 1, wherein a solubility coefficient of carbon dioxide to the curable composition is not less than 0.5 kg/m³·atm and not more than 10 kg/m³·atm.

6. The kit according to claim 1, wherein the layer forming composition contains a solvent (d2), and
if the whole layer forming composition is defined as 100 mass %, a content of the solvent (d2) is not less than 70 mass % and not more than 99.5 mass %.

7. The kit according to claim 1, wherein the layer forming composition does not contain a photopolymerization initiator.

8. The kit according to claim 1, wherein if the whole layer forming composition is defined as 100 mass %, a content of particles whose particle size is larger than 0.2 μm is less than 1 particle/mL.

9. The kit according to claim 1, wherein the layer forming composition contains a compound (a2) having at least one functional group bonded to the substrate and at least one polymerizable functional group (a2), a cross-linker (b2), and a solvent (d2).

10. The kit according to claim 9, wherein if R₁ to R₆ independently indicate one of a hydrogen atom, an alkyl group, an alkoxyalkyl group, and an alkylol group, the cross-linker (b2) is a compound represented by 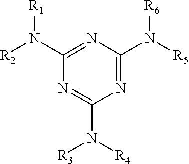
and at least five of R₁ to R₆ are an alkoxyalkyl group or an alkylol group.

11. The kit according to claim 9, wherein the cross-linker (b2) contains at least one substance selected from the group consisting of pentamethoxymethylmelamine, hexamethoxymethylmelamine, (hydroxymethyl)pentakis(methoxymethyl)melamine, hexaethoxymethyl melamine, hexabutoxymethyl melamine, pentamethylol melamine, and hexamethylol melamine.

12. The kit according to claim 9, wherein the cross-linker (b2) is a compound including, in one molecule, at least a total of five groups of one or both of an alkoxyalkyl group and an alkylol group.

13. The kit according to claim 9, wherein the compound (a2) has, in one molecule, at least one of a hydroxyl group, a carboxyl group, a thiol group, an amino group, an epoxy group, and a (block)isocyanate group as the functional group bonded to the substrate.

14. The kit according to claim 9, wherein when weight fractions of the compound (a2) and the cross-linker (b2) with respect to a total weight of the layer forming composition are defined as α and β, respectively, α/β is not less than 0.11 and not more than 9.

15. The kit according to claim 9, wherein when weight fractions of the compound (a2) and the cross-linker (b2) with respect to a total weight of the layer forming composition are defined as α and β, respectively, a sum of α and ρ is not less than 0.01 and not more than 10.

16. The kit according to claim 9, wherein the layer forming composition is a curable composition for imprint.

17. A curable composition containing a polymerizable compound (a1), a photopolymerization initiator (b1), and a solvent (d1), wherein
a viscosity of the curable composition at 23° C. and at 1 atm is not less than 1.3 mPa·s and not more than 60 mPa·s,
a content of the solvent (d1) with respect to a total volume of the polymerizable compound (a1), the photopolymerization initiator (b1), and the solvent (d1) is not less than 5 vol % and not more than 95 vol %,
a boiling point of the solvent (d1) is less than 250° C. at 1 atm,
a contact angle of the curable composition to a silicon substrate is not more than 1.8[°], and
the contact angle of a composition in a state in which the solvent (d1) is removed from the curable composition to the silicon substrate is not less than 11[°] and not more than 19[°].

18. The curable composition according to claim 17, wherein the contact angle of the curable composition to the silicon substrate is not more than 1.0[°].

19. The curable composition according to claim 17, wherein the composition in the state in which the solvent (d1) is removed from the curable composition has a viscosity of not less than 30 mPa·s and not more than 10,000 mPa·s at 23° C. and at 1 atm.

20. A film forming method of forming a film of a curable composition in a space between a mold and a substrate, comprising:
discretely arranging a plurality of droplets of the curable composition defined in claim 17 on the substrate;
waiting until each of the plurality of droplets of the curable composition discretely arranged on the substrate bonds to an adjacent droplet to form a continuous liquid film on the substrate; and
after the waiting, bringing the mold and the liquid film into contact with each other.

21. The method according to claim 20, wherein in the waiting, waiting performed until a solvent contained in the liquid film volatilizes, and a content of the solvent is not more than 10 vol % with respect to the whole liquid film.

22. The method according to claim 20, wherein in the waiting, the substrate is heated under conditions of not less than 30° C. and not more than 200° C. and not less than 10 sec and not more than 600 sec.

23. The method according to claim 20, wherein in the arranging, the droplets of the curable composition having a volume of not less than 1.0 μL are arranged on the substrate at a density of not less than 80 droplets/mm².

24. The method according to claim 20, wherein an average residual liquid film thickness that is a value obtained by dividing a volume of the curable composition remaining after the waiting by an area of a film formation region is not more than 20 nm.

25. The method according to claim 20, wherein the mold includes a pattern,
in the bringing the mold and the liquid film into contact with each other, the pattern of the mold and the liquid film are brought into contact with each other, and
the film forming method further comprises, after the bringing the mold and the liquid film into contact with each other, curing the liquid film to form a cured film having a pattern corresponding to the pattern of the mold.

26. The method according to claim 20, wherein the mold includes a flat surface,
in the bringing the mold and the liquid film into contact with each other, the flat surface of the mold and the liquid film are brought into contact with each other, and
the film forming method further comprises, after the bringing the mold and the liquid film into contact with each other, curing the liquid film to form a cured film having a surface conforming to the flat surface of the mold.

27. The method according to claim 20, wherein in the arranging, the plurality of droplets are discretely arranged on the substrate using an inkjet method.

28. The method according to claim 20, wherein in the bringing the mold and the liquid film into contact with each other, a gas that fills the space between the mold and the substrate contains not less than 10% of carbon dioxide in a molar ratio.

29. An article manufacturing method comprising:
forming a film of a curable composition on a substrate using a film forming method defined in claim 20;
processing the substrate on which the film is formed in the forming; and
manufacturing an article from the substrate processed in the processing.
